(19) United States
(12) Patent Application Publication
(10) Pub. No.: US 2026/0190248 A1
(43) Pub. Date: Jul. 2, 2026

(54) METHOD FOR PRODUCING PRINTED WIRING BOARD, PHOTOSENSITIVE RESIN COMPOSITION, PHOTOSENSITIVE RESIN FILM, PRINTED WIRING BOARD, AND SEMICONDUCTOR PACKAGE

(71) Applicant: Resonac Corporation, Minato-ku, Tokyo (JP)

(72) Inventors: Kohei ABE, Minato-ku, Tokyo (JP); Takeshi NOJIRI, Minato-ku, Tokyo (JP); Hidehiro NAKAMURA, Minato-ku, Tokyo (JP); Shuji NOMOTO, Minato-ku, Tokyo (JP); Akihiro NAKAMURA, Minato-ku, Tokyo (JP); Hayato SAWAMOTO, Minato-ku, Tokyo (JP)

(21) Appl. No.: 18/855,694

(22) PCT Filed: Apr. 5, 2024
(86) PCT No.: PCT/JP2024/014028

§ 371 Date: Oct. 10, 2024

(30) Foreign Application Priority Data
Apr. 19, 2023 (JP) 2023-068467

(51) Int. Cl. H05K 3/46; G03F 7/004; G03F 7/038; H05K 3/00; H05K 3/42

(52) U.S. Cl. CPC H05K 3/4664; G03F 7/0041; G03F 7/038; H05K 3/0041; H05K 3/422; H05K 2203/0594; H05K 2203/066; H05K 2203/072; H05K 2203/0769; H05K 2203/0789

(57) ABSTRACT

The present invention provides a method for producing a printed wiring board that exhibits high adhesive strength with plated copper while reducing surface roughness of an interlayer insulating layer, provides a photosensitive resin composition and a photosensitive resin film that can provide the printed wiring board, and provides the printed wiring board obtained by the method for producing the printed wiring board and a semiconductor package having the printed wiring board. The method for producing the printed wiring board is a method for producing the printed wiring board, the method including the following (1) to (4). (1): Laminating a photosensitive resin film containing particles (X) that dissolve 95% by mass or more in an aqueous sulfuric acid solution having a concentration of 5 to 100 ml/L under conditions of 70° C. for 20 minutes onto one or both sides of a circuit board. (2) Forming an interlayer insulating layer having a via by exposing and developing the photosensitive resin film laminated in the (1). (3-1) Performing roughening treatment on surfaces of the via and the interlayer insulating layer. (3-2) Dissolving the particles (X) present on the surface of the interlayer insulating layer by treating the interlayer insulating layer subjected to the roughening treatment with an acidic solution. (4) Forming a circuit pattern on the interlayer insulating layer.

### TECHNICAL FIELD

The present disclosure relates to a method for producing a printed wiring board, a photosensitive resin composition, a photosensitive resin film, a printed wiring board, and a semiconductor package.

### BACKGROUND ART

In recent years, electronic devices have become smaller and more powerful, and density of printed wiring boards is increasing with an increasing number of circuit layers and refinement of wiring. In particular, density of semiconductor package substrates such as a ball grid array (BGA) and a chip size package (CSP) on which semiconductor chips are mounted has increased significantly, and in addition to the refinement of wiring, there is a demand for thinner insulating layers and further smaller diameter vias (also called via holes) for interlayer connection.

A conventional method for producing the printed wiring board is a method for producing the printed wiring board using a build-up method (for example, see PTL 1), in which an interlayer insulating layer and a conductor circuit layer are sequentially laminated. In the printed wiring board, with the refinement of wiring, a semi-additive method, in which circuits are formed by plating, has become mainstream.

In conventional semi-additive methods, for example, (1) a thermosetting resin film is laminated on a conductor circuit, and then the thermosetting resin film is heated and cured to form the “interlayer insulating layer”. (2) Subsequently, vias for interlayer connection are formed by laser processing, and then desmear treatment and roughening treatment are performed by alkaline permanganate treatment or the like. (3) Thereafter, a substrate is subjected to electroless copper plating treatment, and a pattern is formed using a resist, and then the substrate is subjected to electrolytic copper plating to form a copper circuit layer. (4) Subsequently, the resist is stripped, and then an electroless layer is flash etched to form a copper circuit.

As mentioned above, the laser processing is mainstream as a method for forming the vias in the interlayer insulating layer formed by curing the thermosetting resin film, but reduction in diameter of the vias by laser irradiation using a laser processing machine is reaching a limit. Furthermore, when forming the vias using the laser processing machine, each via hole needs to be formed one by one, and when a large number of vias are required to be provided by means of densification, there is a problem that it takes a long time to form the vias, resulting in poor production efficiency.

Under such circumstances, as a method in which a large number of vias can be collectively formed, there is proposed a method of collectively forming a plurality of reduced-diameter vias by a photolithography method by using a photosensitive resin composition containing an acid-modified vinyl group-containing epoxy resin, a photopolymerizable compound, a photopolymerization initiator, an inorganic filler, and a silane compound, in which the content of the inorganic filler is 10 to 80% by mass (for example, see PTL 2).

In PTL 2, one of issues is to suppress reduction in adhesion to plated copper that results from using the photosensitive resin composition instead of a conventional thermosetting resin composition as a material of the interlayer insulating layer or a surface protective layer, and further resolution of vias and adhesion to a substrate of a silicon material and a chip component are also issues, and these are said to have been solved.

### CITATION LIST

### Patent Literature

PTL 1: JP 7-304931 A
PTL 2: JP 2017-116652 A

### SUMMARY OF INVENTION

### Technical Problem

The refinement of wiring is progressing more and more. One means of achieving further refinement of wiring is a method of reducing surface roughness of the interlayer insulating layer. However, when the surface roughness of the interlayer insulating layer is reduced, the adhesion to the plated copper is reduced, and thus these are in a trade-off relationship. Therefore, it is difficult to achieve both reduction in the surface roughness of the interlayer insulating layer and improved adhesion to the plated copper, and it is not easy to achieve further refinement of wiring.

Therefore, an object of the present disclosure is to provide a method for producing a printed wiring board that exhibits high adhesive strength with the plated copper while reducing the surface roughness of the interlayer insulating layer, to provide a photosensitive resin composition and a photosensitive resin film that can provide the printed wiring board, and to provide the printed wiring board obtained by the method for producing the printed wiring board and a semiconductor package having the printed wiring board.

### Solution to Problem

As a result of diligent research, the present inventors have found that the above object can be achieved by the present disclosure.

The present disclosure includes the following embodiments [1] to [16].
[1] A method for producing a printed wiring board, the method including the following (1) to (4):
(1): Laminating a photosensitive resin film containing particles (X) that dissolve 95% by mass or more in an aqueous sulfuric acid solution having a concentration of 5 to 100 ml/L under conditions of 70° C. for 20 minutes onto one or both sides of a circuit board;
(2) Forming an interlayer insulating layer having a via by exposing and developing the photosensitive resin film laminated in the (1);
(3-1) Performing roughening treatment on surfaces of the via and the interlayer insulating layer;
(3-2) Dissolving the particles (X) present on the surface of the interlayer insulating layer by treating the interlayer insulating layer subjected to the roughening treatment with an acidic solution; and
(4) Forming a circuit pattern on the interlayer insulating layer.
[2] The method for producing the printed wiring board according to the above [1], in which the roughening treatment in the above (3-1) is performed using a roughening liquid.
[3] The method for producing the printed wiring board according to the above [1], in which the roughening treatment in the above (3-1) is performed by dry etching.
[4] The method for producing the printed wiring board according to any one of the above [1] to [3], in which surface roughness (Ra) of the interlayer insulating layer after the roughening treatment in the above (3-1) is 0.30 μm or less.
[5] The method for producing the printed wiring board according to any one of the above [1] to [4], in which the acidic solution used in the above (3-2) contains an aqueous sulfuric acid solution.
[6] The method for producing the printed wiring board according to any one of the above [1] to [5], in which the particles (X) have a volume average particle diameter of 0.1 to 3 μm.
[7] The method for producing the printed wiring board according to any one of the above [1] to [6], in which the photosensitive resin film contains 10 to 70 vol % of the particles (X).
[8] A photosensitive resin composition containing particles (X) that dissolve 95% by mass or more in an aqueous sulfuric acid solution having a concentration of 5 to 100 ml/L under conditions of 70° C. for 20 minutes.
[9] The photosensitive resin composition according to the above [8], further containing a component (A): a photopolymerizable compound having an ethylenically unsaturated group and an acidic substituent, and a component (B): a thermosetting resin.
[10] The photosensitive resin composition according to the above [9], in which the component (A) contains an alicyclic skeleton represented by the following general formula (A-1).

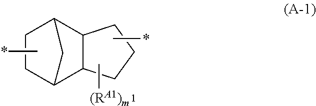

(In the formula, R^{A1} represents an alkyl group having 1 to 12 carbon atoms and may be substituted anywhere in the alicyclic skeleton. m¹ is an integer from 0 to 6. * is a bonding site to another structure.)
[11] The photosensitive resin composition according to any one of the above [8] to [10], in which an average particle diameter of the particles (X) is 0.1 to 3 μm.
[12] The photosensitive resin composition according to any one of the above [8] to [11], in which a content of the particles (X) is 10 to 70 vol % based on a total solid content.
[13] A photosensitive resin composition for forming a photo via, containing the photosensitive resin composition according to any one of the above [8] to [12].
[14] A photosensitive resin film containing the photosensitive resin composition according to any one of the above [8] to [12].
[15] A printed wiring board containing the photosensitive resin composition according to any one of the above [8] to [12] or the photosensitive resin film according to the above [14].
[16] A semiconductor package containing the printed wiring board according to the above [15] and a semiconductor element.

### Advantageous Effects of Invention

According to the present disclosure, it is possible to provide a method for producing a printed wiring board that exhibits high adhesive strength with the plated copper while reducing the surface roughness of the interlayer insulating layer, to provide a photosensitive resin composition and a photosensitive resin film that can provide the printed wiring board, and to provide the printed wiring board obtained by the method for producing the printed wiring board and a semiconductor package having the printed wiring board.

### BRIEF DESCRIPTION OF DRAWINGS

FIG. 1 is a schematic diagram indicating a lamination step (1).

FIG. 2 is a schematic diagram indicating a photo via forming step (2).

FIG. 3 is a schematic diagram indicating a roughening treatment step (3-1).

FIG. 4 is a schematic diagram indicating a particle (X) dissolving step (3-2).

FIG. 5 is a schematic diagram indicating a circuit pattern forming step (4).

FIG. 6 is a schematic diagram of a multilayered printed wiring board.

FIG. 7 is an SEM image of a via formed in Example 2.

FIG. 8 is an SEM image of the via formed in Example 11.

FIG. 9 is an SEM image of a surface of an interlayer insulating layer after the particle (X) dissolving step (3-2) in Example 2.

FIG. 10 is an SEM image of the surface of the interlayer insulating layer after the particle (X) dissolving step (3-2) in Example 5.

FIG. 11 is an SEM image of the surface of the interlayer insulating layer after the particle (X) dissolving step (3-2) in Example 8.

FIG. 12 is an SEM image of the surface of the interlayer insulating layer after the particle (X) dissolving step (3-2) in Example 11.

FIG. 13 is an SEM image of the surface of the interlayer insulating layer after the particle (X) dissolving step (3-2) in Comparative Example 5.

FIG. 14 is an SEM image of the surface of the interlayer insulating layer after the roughening treatment step (3-1) in Example 13.

FIG. 15 is SEM image of the surface of the interlayer insulating layer after the particle (X) dissolving step (3-2) in Example 13.

### DESCRIPTION OF EMBODIMENTS

In a numerical value range described in the present disclosure, an upper limit value or a lower limit value in a respective numerical value range may be substituted by a value described in Examples. In addition, the lower limit value and the upper limit value in the numerical value range are each arbitrarily combined with a lower limit value or an upper limit value of another numerical value range. In the notation of the numerical value range “AA to BB”, the numerical values AA and BB at both ends are included in the numerical range as the lower limit value and the upper limit value, respectively.

In the present disclosure, for example, the description “10 or more” means 10 and numerical values exceeding 10, and the same applies when the numerical values are different. Further, for example, the description “10 or less” means 10 and numerical values less than 10, and the same applies when the numerical values are different.

In the present disclosure, when there are a plurality of types of substances corresponding to each component, the content of each component in a photosensitive resin composition means a total content of the plurality of types of substances existing in the photosensitive resin composition unless otherwise indicated.

In the present disclosure, the “number of ring-forming carbon atoms” is the number of carbon atoms necessary for forming a ring, and does not include the number of carbon atoms of a substituent on the ring. For example, in both a cyclohexane skeleton and a methylcyclohexane skeleton, the number of ring-forming carbon atoms is 6.

The notation “XX (meth)acrylate” means one or both of XX acrylate and XX methacrylate. Further, a “(meth)acryloyl group” means one or both of an acryloyl group and a methacryloyl group.

In the present disclosure, “resin components” are a component (A), a component (B), and the like described below, and also includes other components (for example, components (C), (D), (F), (G), (H), (I), (J), and the like) that may be contained as necessary, but does not include inorganic compounds such as an inorganic filler and a pigment. Further, a “solid content” refers to a nonvolatile content excluding water and a diluent described below contained in the photosensitive resin composition, and also includes those which are in a liquid state, a starch syrup-like state, or a waxy state at room temperature around 25° C.

In the present disclosure, a “relative dielectric constant” refers to a relative dielectric constant in the 10 GHz band, unless otherwise explained.

In addition, the present embodiment also includes aspects in which matters described in the present disclosure are arbitrarily combined.

### [Method for Producing a Printed Wiring Board]

A method for producing a printed wiring board according to an embodiment of the present disclosure (hereinafter, sometimes simply referred to as the present embodiment) is a method for producing a printed wiring board, including the following (1) to (4).
(1) Laminating a photosensitive resin film containing particles (X) (hereinafter, sometimes simply referred to as “particles (X)”) that dissolve 95% by mass or more in an aqueous sulfuric acid solution having a concentration of 5 to 100 ml/L under conditions of 70° C. for 20 minutes onto one or both sides of a circuit board (hereinafter, referred to as “lamination step (1)”).
(2) Forming an interlayer insulating layer having a via by exposing and developing the photosensitive resin film laminated in the (1) (hereinafter, referred to as “photo via forming step
(2)”).
(3-1) Performing roughening treatment on surfaces of the via and the interlayer insulating layer (hereinafter, referred to as “roughening treatment step (3-1)”).
(3-2) Dissolving the particles (X) present on the surface of the interlayer insulating layer by treating the interlayer insulating layer subjected to the roughening treatment with an acidic solution (hereinafter referred to as “particle (X) dissolving step (3-2)”).
(4) Forming a circuit pattern on the interlayer insulating layer (hereinafter referred to as “circuit pattern forming step (4)”).

Here, as mentioned above, in the present disclosure, for convenience, a certain operation may be referred to as “XX step”, but the XX step is not limited to only aspects specifically described in the present disclosure.

In the present embodiment, by providing the particle (X) dissolving step (3-2) after the roughening treatment step (3-1), the particles (X) present on the surface of the interlayer insulating layer can be dissolved to create recesses on the surface of the interlayer insulating layer, thereby making it possible to obtain high adhesive strength with plated copper while reducing surface roughness of the interlayer insulating layer.

Each step will be described in order below.

### (Lamination Step (1))

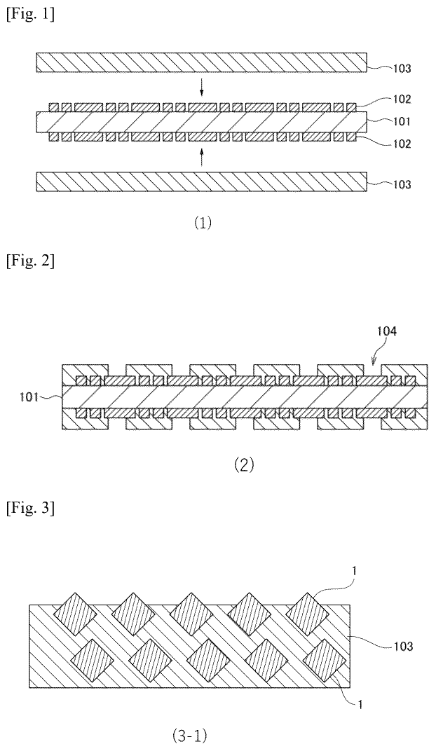

The lamination step (1) is a step of laminating the photosensitive resin film of the present embodiment onto one or both sides of the circuit board (a substrate 101 having a circuit pattern 102) using a vacuum laminator (see FIG. 1). Examples of the vacuum laminator include a vacuum applicator manufactured by Nikko-Materials Co., Ltd. and a vacuum pressure laminator manufactured by The Japan Steel Works, Ltd.

When a protective film is provided on the photosensitive resin film, the protective film can be peeled off or removed, and then the photosensitive resin film can be laminated by pressing to the circuit board while being pressed and heated in a state where the photosensitive resin film is in contact with the circuit board.

The lamination can be carried out, for example, after preheating the photosensitive resin film and the circuit board as necessary, at a pressing temperature of 70° C. to 130° C., a pressing pressure of 0.1 MPa to 1.0 MPa, and a reduced pressure of air pressure of 20 mmHg (26.7 hPa) or less, but is not particularly limited to this condition. Further, the lamination method may be a batch method or a continuous method using a roll.

Finally, the photosensitive resin film laminated to the circuit board is cooled to around 25° C. to form an interlayer insulating layer 103. When the photosensitive resin film has a carrier film, the carrier film may be peeled off at this point, or may be peeled off after exposure, as described below.

### (Photo Via Forming Step (2))

In the photo via forming step (2), at least a portion of the photosensitive resin film laminated to the circuit board is exposed to light, and then developed. A portion irradiated with active rays are photocured by exposure to form a pattern. There is no particular limitation on an exposure method, and for example, a method (a mask exposure method) of irradiating active rays in an image-like manner via or through a negative or positive mask pattern that is called an artwork may be adopted, or a method of irradiating active rays in an image-like manner by a direct drawing exposure method such as a laser direct imaging (LDI) exposure method and a digital light processing (DLP) exposure method may be adopted.

A known light source can be used as a light source of the active rays. Specific examples of the light source include light sources that effectively radiate ultraviolet or visible light, such as gas lasers such as carbon arc lamps, mercury vapor arc lamps, high-pressure mercury lamps, xenon lamps, and argon lasers, solid-state lasers such as YAG lasers, and semiconductor lasers. An amount of exposure is appropriately selected depending on the light source used and a thickness of a photosensitive layer, but for example, in the case of ultraviolet irradiation from the high-pressure mercury lamp, when the thickness of the photosensitive layer is 1 to 100 μm, typically about 10 to 1,000 mJ/cm² is preferred, 50 to 700 mJ/cm² is more preferred, and 150 to 550 mJ/cm² is even more preferred.

During development, an uncured portion of the photosensitive layer is removed from the substrate, to form a photocured portion on the substrate as the interlayer insulating layer.

When the carrier film is present on the photosensitive layer, the carrier film is removed, and then an unexposed portion is removed (developed). There are wet development and dry development as a development method, and either may be used, but the wet development is widely used, and the wet development can also be used in the present embodiment.

In the case of wet development, the development is performed by a known development method with a developer corresponding to the photosensitive resin composition. Examples of the development method include a dip method, a battle method, a spray method, blushing, slapping, scrapping, and rocking immersion. Of these, from the viewpoint of improving resolution of via, the spray method is preferred, and a high-pressure spray method is more preferred among the spray methods. The development may be carried out by a single method or may be carried out by a combination of two or more methods.

The constitution of the developer is appropriately selected according to the constitution of the photosensitive resin composition. Examples of the developer include an alkaline aqueous solution, a water-based developer, and an organic solvent-based developer, and of these, an alkaline aqueous solution is preferred.

In the photo via forming step (2), after performing the exposure and the development, by optionally performing post UV curing with an exposure amount of about 0.2 to 10 J/cm² (preferably 0.5 to 5 J/cm²) and post thermal curing at a temperature of about 60 to 250° C. (preferably 120 to 200° C.), the interlayer insulating layer may be further cured, and is more preferably cured.

By the above method, an interlayer insulating layer having vias 104 is formed (see FIG. 2). There is no particular limitation on a shape of the via, and examples of a sectional shape include a rectangle and an inverted trapezoid (an upper side is longer than a lower side), and examples of a shape seen from a front (a direction in which a via bottom can be seen) include a circle and a rectangle. In formation of the via by a photolithography method in the present embodiment, the via having the sectional shape of an inverted trapezoid (the top side is longer than the bottom side) can be formed, and in this case, it is preferred because adhesion of the plated copper on a via wall surface is increased.

The size (diameter) of the via 104 formed by this step can be less than 40 μm, and can even be 35 μm or less, 30 μm or less, 25 μm or less, or 20 μm or less, which is smaller than the size of the via prepared by laser processing. There is no particular limitation on a lower limit of the size (diameter) of the via formed by this step, but it may be 5 μm or more, 10 μm or more, or 15 μm or more.

However, the size (diameter) of the via 104 formed by this step is not limited to less than 40 μm, and may be arbitrarily selected in a range of, for example, 5 to 300 μm, and may be 15 to 100 μm or 20 to 80 μm.

### (Roughening Treatment Step (3-1))

In the roughening treatment step (3-1), the roughening treatment is performed on the surfaces of the via and the interlayer insulating layer (see FIG. 3). By the roughening treatment, anchors with fine irregularities are formed on the surfaces of the via and the interlayer insulating layer. From the viewpoint of refinement of wiring, the surface roughness (Ra) of the interlayer insulating layer after the roughening treatment is preferably 0.30 μm or less, more preferably 0.25 μm or less, even more preferably 0.01 to 0.12 μm, particularly preferably 0.02 to 0.10 μm, and most preferably 0.02 to 0.09 μm.

Here, in the present disclosure, the surface roughness (Ra) is a result of measurement using a high-performance non-contact three-dimensional surface profile roughness measurement system (Wyko NT9100, manufactured by Bruker Japan Co., Ltd.), and is specifically a value measured by a method described in Examples.

There is no particular limitation on the roughening treatment method, and any known roughening treatment method for the via and the interlayer insulating layer can be used. The roughening treatment method is not particularly limited, but examples thereof include a method carried out using a roughening liquid and a method carried out by dry etching. Here, the method carried out using the roughening liquid is also called wet etching.

An oxidizing agent can be used as the roughening liquid. Examples of the oxidizing agent include: an alkaline permanganate solution in which potassium permanganate, sodium permanganate, or the like is dissolved in an aqueous solution of sodium hydroxide; dichromate; ozone; hydrogen peroxide-sulfuric acid; and nitric acid. The concentration of permanganate in the alkaline permanganate solution is preferably 5 to 10% by mass. Examples of commercially available oxidizing agents include alkaline permanganate solutions such as Concentrate Compact CP and Dosing Solution Securiganth (registered trademark) P (both manufactured by Atotech Japan K.K.). Note that when smears occur in the photo via forming step (2), the smears may be removed by the roughening liquid. The roughening treatment and smear removal (desmear) can be performed simultaneously.

When the roughening liquid is used, preferably, swelling treatment is performed on a via surface and an interlayer insulating layer surface, and then the roughening treatment is performed on the via surface and the interlayer insulating layer surface. A commercially available swelling liquid can be used for the swelling treatment. Examples of the swelling liquid include an alkaline solution and a surfactant solution, and an alkaline solution is preferred. Examples of the alkaline solution include a sodium hydroxide solution and a potassium hydroxide solution. Examples of commercially available swelling liquids include Swelling Dip Securiganth (registered trademark) P and Swelling Dip Securiganth (registered trademark) SBU (both manufactured by Atotech Japan K.K.). There is no particular limitation on time and temperature of the swelling treatment, but it is preferably 50 to 90° C., and more preferably 60 to 80° C., and is preferably 1 to 20 minutes, more preferably 3 to 15 minutes, and even more preferably 3 to 8 minutes.

Note that after the swelling treatment and the roughening treatment, a water washing treatment may be performed as necessary. There is no particular limitation on time and temperature of the water washing treatment, but it is preferably 5 to 40° C., and more preferably 15 to 30° C., and is preferably 0.1 to 10 minutes, and more preferably 0.5 to 7 minutes. The water washing treatment may involve a combination of so-called “stored water washing”, in which water is simply stored, and so-called “running water washing”, in which water is allowed to flow, or only one of them may be performed, but it is preferable to perform at least the running water washing, and it is more preferable to perform both the stored water washing and the running water washing.

Examples of the dry etching include reactive ion etching (RIE), and examples of the RIE include dry etching using a reactive gas and dry etching using plasma. Of these, the dry etching using plasma is preferred as dry etching. For the dry etching using plasma, a commercially available plasma etching device may be used. There is no particular limitation on conditions for the dry etching using plasma, but it is preferable to use oxygen plasma, and an output is preferably 100 to 500 W, and more preferably 200 to 400 W.

There is no particular limitation on time and temperature of the dry etching, but it is preferably 5 to 40° C., and more preferably 15 to 30° C., and is preferably 0.1 to 10 minutes, and more preferably 0.5 to 7 minutes.

As a result of the roughening treatment step (3-1), as illustrated in FIG. 3, some of the particles (X) appear to protrude from the surface of the interlayer insulating layer 103. Note that the particles (X) will be described later.

### (Particle (X) Dissolving Step (3-2))

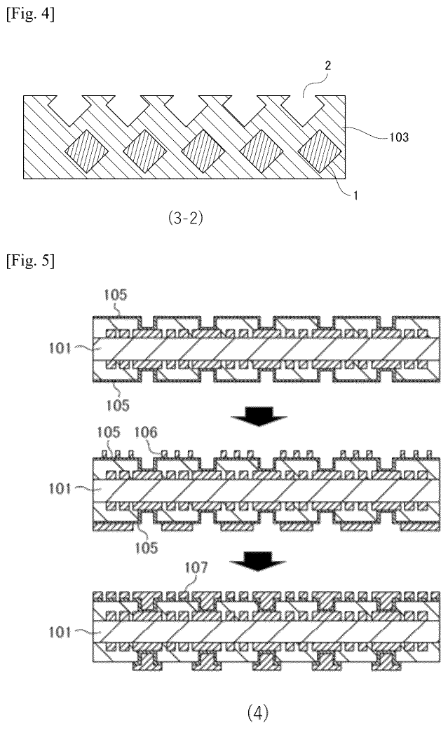

In the particle (X) dissolving step (3-2), the roughened interlayer insulating layer is treated with the acidic solution to dissolve the particles (X) present on the surface of the interlayer insulating layer (see FIG. 4).

The acidic solution is not particularly limited, but examples thereof include an aqueous sulfuric acid solution, an aqueous hydrochloric acid solution, an aqueous sodium persulfate solution, an aqueous ammonium persulfate solution, and an aqueous potassium persulfate solution. The acidic solution preferably contains the aqueous sulfuric acid solution or the aqueous hydrochloric acid solution, more preferably contains the aqueous sulfuric acid solution, and even more preferably is an aqueous sulfuric acid solution.

From the viewpoint of solubility of the particles (X), the concentration of the aqueous sulfuric acid solution is preferably 5 to 100 ml/L, more preferably 10 to 80 ml/L, and even more preferably 15 to 50 ml/L, and may be 10 to 30 ml/L, 35 to 80 ml/L, or 35 to 60 ml/L.

From the viewpoint of the solubility of the particles (X), the concentration of the aqueous hydrochloric acid solution is preferably 5 to 100 g/L, more preferably 10 to 80 g/L, and even more preferably 15 to 50 g/L, and may be 10 to 30 ml/L, 35 to 80 ml/L, or 35 to 60 ml/L.

Note that although not particularly limited, it is preferable that the acidic solution is not a toxic one (for example, hydrofluoric acid).

Note that the particle (X) dissolving step (3-2) may be provided before or during the circuit pattern forming step (4) described below.

Further, the particle (X) dissolving step (3-2) can be considered as a neutralization step after the roughening treatment when the roughening liquid is used in the roughening treatment step (3-1), or as a pretreatment for forming a seed layer when a semi-additive process is performed in the circuit pattern forming step (4) described below when the dry etching is performed in the roughening treatment step (3-1). In any case, it is important that the particle (X) dissolving step (3-2) dissolves the particles (X) present on the interlayer insulating layer surface to create recesses 2 as illustrated in FIG. 4.

From the viewpoint of the solubility of the particles (X), a temperature when treating the interlayer insulating layer with the acidic solution is preferably 15 to 80° C., more preferably 20 to 75° C., and even more preferably 25 to 70° C., and may be 40 to 70° C., 50 to 70° C., or 60 to 70° C.

A time for treating the interlayer insulating layer with the acidic solution is not particularly limited, but from the viewpoint of the solubility of the particles (X), it is preferably 0.1 to 40 minutes, more preferably 0.3 to 35 minutes, even more preferably 3 to 30 minutes, particularly preferably 5 to 25 minutes, and most preferably 15 to 25 minutes.

There is no particular limitation on a method for treating the interlayer insulating layer with the acidic solution, but examples thereof include (1) a method in which a substrate having the interlayer insulating layer is immersed in the acidic solution and, if necessary, the substrate having the interlayer insulating layer is rocked, (2) a method in which the substrate having the interlayer insulating layer is immersed in the acidic solution and, if necessary, the acidic solution is stirred, and (3) a method in which the acidic solution is sprayed onto the interlayer insulating layer. From the viewpoint of the solubility of the particles (X), the above method (1) or (2) is preferred.

After the treatment with the acidic solution, the water washing treatment may be performed as necessary. There is no particular limitation on the time and temperature of the water washing treatment, but it is preferably 5 to 40° C., and more preferably 15 to 30° C., and is preferably 0.1 to 10 minutes, and more preferably 0.5 to 7 minutes. The water washing treatment may involve the combination of the stored water washing and the running water washing, or only one of them may be performed, but it is preferable to perform at least the running water washing, and it is more preferable to perform both the stored water washing and the running water washing.

### (Circuit Pattern Forming Step (4))

The circuit pattern forming step (4) is a step of forming a circuit pattern on the interlayer insulating layer after the particle (X) dissolving step (3-2) (see FIG. 5).

Formation of the circuit pattern is preferably performed by the semi-additive process from the viewpoint of forming fine wiring. Conduction of the via is performed along with the formation of the circuit pattern by the semi-additive process.

In the semi-additive process, first, the via bottom, the via wall surface, and the entire surface of the interlayer insulating layer after the particle (X) dissolving process (3-2) are subjected to electroless copper plating treatment using a palladium catalyst or the like, to form a seed layer 105. The seed layer is one for forming a power supply layer for the purpose of performing electrolytic copper plating and is preferably formed in a thickness of about 0.1 to 2.0 μm. When the thickness of the seed layer is 0.1 μm or more, there is a tendency that reduction in connection reliability during electrolytic copper plating can be suppressed, and when it is 2.0 μm or less, there is no need to increase an etching amount during flash etching of the seed layer between wirings, and there is a tendency that damage given to the wiring during etching is suppressed.

Note that as pretreatment before the formation of the seed layer, cleaner treatment (also called conditioner treatment) and the water washing treatment, as well as soft etching and the water washing treatment may be performed as necessary.

The cleaner treatment may be performed with a commercially available alkaline cleaner (conditioner liquid) at preferably 40 to 80° C., and more preferably 50 to 70° C., for preferably 0.1 to 10 minutes, and more preferably 0.5 to 7 minutes. The water washing treatment after the cleaner treatment is described in the same manner as the water washing treatment described above, and preferred aspects are also the same.

The soft etching can be performed by treating with sodium persulfate and sulfuric acid, or ammonium persulfate and sulfuric acid, at preferably 10 to 40° C., and more preferably 20 to 35° C., for preferably 0.1 to 3 minutes, and more preferably 0.3 to 1 minute. The water washing treatment after the soft etching is described in the same manner as the water washing treatment described above, and the preferred aspects are also the same. The soft etching can also be performed as the particle (X) dissolving step (3-2).

The electroless copper plating treatment is performed by reacting copper ions with a reducing agent to precipitate metallic copper on the surfaces of the via and the interlayer insulating layer.

The electroless plating treatment method and the electrolytic plating treatment method may be any known method and are not particularly limited.

As an electroless copper plating solution, a commercially available product can be used, and examples of the commercially available product include “MSK-DK” manufactured by Atotech Japan K.K. and “Thru-Cup (registered trademark) PEA series” manufactured by C. Uyemura & Co., Ltd.

After the electroless copper plating process, a dry film resist is thermocompressed on the electroless copper plating using a roll laminator. A thickness of the dry film resist must be higher than a wiring height after electrolytic copper plating, and from this viewpoint, a dry film resist having a thickness of 5 to 30 μm is preferred. As the dry film resist, “Photec (registered trademark)” series or the like manufactured by Resonac Corporation is used.

After the dry film resist is thermocompressed, the dry film resist is exposed, for example, through a mask on which a desired wiring pattern is drawn. The exposure can be performed using the same device and light source as those that can be used when the via is formed in the photosensitive resin film. After the exposure, the dry film resist is developed using an alkaline aqueous solution, and the unexposed portion is removed to form a resist pattern 106. Thereafter, if necessary, a work of removing development residues of the dry film resist using plasma or the like may be performed.

After the development, by performing the electrolytic copper plating, a copper circuit layer (circuit pattern) 107 is formed and via filling is performed.

After electrolytic copper plating, the dry film resist is stripped using an alkaline aqueous solution or an amine-based stripping agent. After stripping off the dry film resist, removal (flash etching) of the seed layer between the wirings is performed. The flash etching is performed using an acidic solution such as sulfuric acid and hydrogen peroxide, and an oxidizing solution. After the flash etching, removal of palladium and the like adhering to a portion between the wirings is performed as necessary. The removal of palladium can be preferably performed using an acidic solution such as nitric acid or hydrochloric acid.

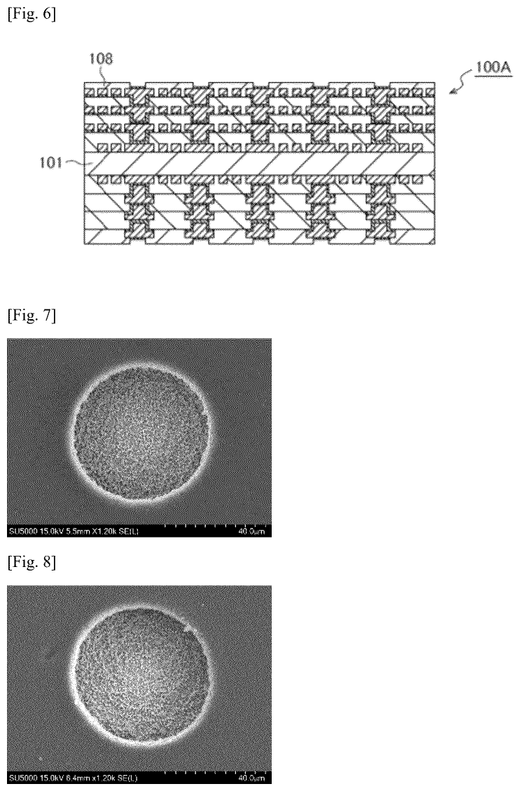

After stripping of the dry film resist or after a flash etching step, a post-baking treatment is preferably performed. The post-baking treatment can sufficiently heat-cure an unreacted thermosetting component, which tends to improve insulation reliability, curing characteristics, and adhesive strength with the plated copper. Thermal curing conditions vary depending on the type of resin composition, and the like, but it is preferable that a curing temperature is 150 to 240° C., and a curing time is 15 to 100 minutes. The post-baking treatment completes a production process of a printed wiring board 100A by a general photo via method, but a multi-layered printed wiring board 100A is produced by repeating this process according to the number of required interlayer insulating layers (see FIG. 6). Then, a solder resist layer 108 is preferably formed as the outermost layer.

### [Photosensitive Resin Composition]

The photosensitive resin composition of the present embodiment is a photosensitive resin composition containing particles (X) that dissolve 95% by mass or more in the aqueous sulfuric acid solution having a concentration of 5 to 100 ml/L under the conditions of 70° C. for 20 minutes. By using the photosensitive resin composition as a material of the interlayer insulating layer of the printed wiring board, it is possible to dissolve the particles (X) in the particle (X) dissolving step (3-2).

The photosensitive resin composition of the present embodiment is suitable for via formation by photolithography (also referred to as photo via formation), and is therefore suitable for formation of one or more types selected from the group consisting of a photo via and the interlayer insulating layer. Here, in the present disclosure, when it is written, for example, like a “layer” such as an interlayer insulating layer, in addition to an aspect that is a solid layer, the “layer” also includes an aspect that is not the solid layer but has at least an island-like portion, an aspect having a hole, a case where an interface with an adjacent layer is unclear, and the like. Note that the solid layer refers to a sheet-like layer that has not been particularly processed.

Note that the photosensitive resin composition of the present embodiment is suitable for a negative photosensitive resin composition.

The particles (X) will be described in detail below, and then other components that can be contained in the photosensitive resin composition of the present embodiment will be described in detail.

### <Particles (X)>

As described above, the particles (X) are particles that dissolve 95% by mass or more in the aqueous sulfuric acid solution having a concentration of 5 to 100 ml/L under the conditions of 70° C. for 20 minutes. The particles (X) are particles that are easily dissolved in the particle (X) dissolving step (3-2). The concentration of the aqueous sulfuric acid solution is preferably 10 to 80 ml/L, and more preferably 15 to 50 ml/L, from the viewpoint of the solubility of the particles (X) in the particle (X) dissolving step (3-2).

The particles (X) may be particles that dissolve 97% by mass or more in the aqueous sulfuric acid solution having a concentration of 5 to 100 ml/L under the conditions of 70° C. for 20 minutes, more preferably particles that dissolve 99% by mass or more, and may be particles that dissolve 100% by mass. Here, the amount of dissolution is an amount of dissolution when the particles (X) are submerged in the aqueous sulfuric acid solution and stirred at 70° C. for 1 hour. The amount of dissolution of the particles (X) can be calculated from a weight of particles (X) obtained by submerging the particles (X) in the aqueous sulfuric acid solution of the specified concentration under the conditions of 70° C. for 20 minutes and then filtering the solution. Note that when no solid content is obtained upon filtration, it can be said that the particles (X) are 100% dissolved.

The particles (X) may be inorganic particles or organic particles.

The inorganic particles are not particularly limited, but examples thereof include: magnesium-containing inorganic particles such as magnesium hydroxide, magnesium carbonate, magnesium oxide, magnesium peroxide, magnesium diboride, magnesium nitride, magnesium sulfide, calcium magnesium carbonate, magnesium nitrate, magnesium sulfate, magnesium sulfite, trimagnesium phosphate, magnesium phosphate, spinel, talc, and serpentine; calcium-containing inorganic particles such as calcium oxide, calcium hydroxide, calcium sulfide, calcium sulfate, calcium hydrogen sulfate, calcium thiosulfate, calcium sulfite, calcium selenide, calcium selenate, calcium nitrite, calcium phosphate, calcium carbonate, calcium hydrogen carbonate, calcium metasilicate, calcium tetraborate, calcium chromate, and calcium dichromate; and zinc-containing inorganic particles such as zinc oxide, zinc hydroxide, zinc sulfate, zinc nitrate, and zinc carbonate. Of these, from the viewpoint of the solubility of the particles (X) in the particle (X) dissolving step (3-2), the magnesium-containing inorganic particles and the zinc-containing inorganic particles are preferred, magnesium hydroxide, magnesium carbonate, and zinc oxide are more preferred, and magnesium hydroxide and magnesium carbonate are even more preferred.

The organic particles are not particularly limited, but examples thereof include melamine resin, benzoguanamine, polyadamantyl (meth)acrylate, poly-t-butyl (meth)acrylate and polyacrylic acid. Of these, from the viewpoint of the solubility of the particles (X) in the particle (X) dissolving step (3-2), polyadamantyl (meth)acrylate and poly-t-butyl (meth)acrylate are preferred.

A volume average particle diameter of the particles (X) is not particularly limited, but from the viewpoint of peel strength with the plated copper, it is preferably 0.1 to 3 μm, more preferably 0.2 to 2.0 μm, even more preferably 0.3 to 1.7 μm, and particularly preferably 0.3 to 1.5 μm, and may be 0.5 to 1.5 μm or 0.7 to 1.5 μm.

Here, in the present disclosure, the volume average particle diameter is determined as a particle diameter equivalent to an integrated value of 50% (volume basis) in a particle size distribution by measuring particles dispersed in a solvent at a refractive index of 1.38 in accordance with ISO 13321 using a submicron particle analyzer (manufactured by Beckman Coulter, Inc., trade name: N5).

In the photosensitive resin composition of the present embodiment, the content of the particles (X) is not particularly limited, but is preferably 10 to 70 vol %, more preferably 15 to 60 vol %, and even more preferably 20 to 55 vol %, and may be 25 to 50 vol %, or 25 to 40 vol %, based on a total solid content. When the content of the particles (X) is the lower limit or more, the high adhesive strength with the plated copper tends to be exhibited while reducing the surface roughness of the interlayer insulating layer, and when it is the upper limit or less, good resolution tends to be maintained.

Note that when the content of the particles (X) is 15 vol % or more based on the total solid content, an effect of improving the high adhesive strength with the plated copper tends to be even greater.

The photosensitive resin composition of the present embodiment preferably further contains a photopolymerizable compound (A) having an ethylenically unsaturated group and an acidic substituent, and a thermosetting resin (B). The components (A) and (B) will be described in detail in this order below, and then the other components will be also described in detail.

### <Photopolymerizable Compound (A) Having Ethylenically Unsaturated Group and Acidic Substituent>

The component (A) is a photopolymerizable compound having the ethylenically unsaturated group and the acidic substituent.

One type of the component (A) may be used alone, or two or more types thereof may be used in combination.

The component (A) has the ethylenically unsaturated group and thus is a compound that exhibits photopolymerizability, in particular radical polymerizability.

Examples of the ethylenically unsaturated group contained in the component (A) include functional groups that exhibit photopolymerizability, such as vinyl groups, allyl groups, propargyl groups, butenyl groups, ethynyl groups, phenylethynyl groups, maleimide groups, nadimide groups, and (meth)acryloyl groups. Of these, (meth)acryloyl groups are preferred from the viewpoints of reactivity and the resolution of via.

The component (A) has the acidic substituent from the viewpoint of enabling alkaline development.

Examples of the acidic substituent contained in the component (A) include a carboxy group, a sulfonic acid group, and a phenolic hydroxyl group. Of these, the carboxy group is preferred from the viewpoint of the resolution of via.

An acid value of the component (A) is preferably 20 to 200 mgKOH/g, more preferably 40 to 180 mgKOH/g, even more preferably 70 to 150 mgKOH/g, and particularly preferably 90 to 120 mgKOH/g. When the acid value of the component (A) is the lower limit or more, solubility of the photosensitive resin film in a dilute alkaline solution tends to be excellent, and when it is the upper limit or less, a relative dielectric constant tends to be excellent. The acid value of the component (A) can be measured by a method described in Examples.

Note that two or more types of the component (A) having different acid values may be used in combination, and in this case, it is preferable that a weight average acid value of the acid values of the two or more types of the component (A) falls within any of the ranges described above.

A weight average molecular weight (Mw) of the component (A) is preferably 600 to 30,000, more preferably 800 to 25,000, even more preferably 1,000 to 18,000, still even more preferably 1,000 to 8,000, particularly preferably 1,200 to 5,000, and most preferably 1,200 to 3,500. When the weight average molecular weight (Mw) of the component (A) is within the above range, the adhesive strength with the plated copper, heat resistance, and the insulation reliability tend to be excellent. Here, in the present disclosure, the weight average molecular weight is a value determined by gel permeation chromatography (GPC) method using tetrahydrofuran as a solvent and converted into standard polystyrene, and in detail, is a value measured according to a method described in Examples.

From the viewpoint of the relative dielectric constant, the component (A) preferably contains an alicyclic skeleton, but may not contain the alicyclic skeleton.

From the viewpoints of the resolution of via, the adhesive strength with the plated copper, and electrical insulation reliability, the alicyclic skeleton contained in the component (A) is preferably an alicyclic skeleton having 5 to 20 ring carbon atoms, more preferably an alicyclic skeleton having 5 to 18 ring carbon atoms, even more preferably an alicyclic skeleton having 6 to 18 ring carbon atoms, particularly preferably an alicyclic skeleton having 8 to 14 ring carbon atoms, and most preferably an alicyclic skeleton having 8 to 12 ring carbon atoms.

Further, from the viewpoints of the resolution of via, the adhesive strength with the plated copper, and the electrical insulation reliability, the alicyclic skeleton is preferably constituted of two or more rings, more preferably constituted of two to four rings, and even more preferably constituted of three rings. Examples of the alicyclic skeleton having two or more rings include a norbornane skeleton, a decalin skeleton, a bicycloundecane skeleton, and a saturated dicyclopentadiene skeleton. Of these, the saturated dicyclopentadiene skeleton is preferred from the viewpoints of the resolution of via, the adhesive strength with the plated copper, and the electrical insulation reliability.

From the same viewpoints, the component (A) containing an alicyclic skeleton represented by the following general formula (A-1) is preferred.

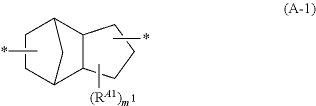

(In the formula, R^{A1} represents an alkyl group having 1 to 12 carbon atoms and may be substituted anywhere in the alicyclic skeleton. m¹ is an integer from 0 to 6. * is a bonding site to another structure.)

In the general formula (A-1), examples of the alkyl group having 1 to 12 carbon atoms represented by R^{A1} include a methyl group, an ethyl group, an n-propyl group, an isopropyl group, an n-butyl group, an isobutyl group, a t-butyl group, and an n-pentyl group. As the alkyl group, an alkyl group having 1 to 6 carbon atoms is preferred, an alkyl group having 1 to 3 carbon atoms is more preferred, and a methyl group is even more preferred.

m¹ is an integer from 0 to 6, preferably an integer from 0 to 2, and more preferably 0.

When m¹ is the integer from 2 to 6, a plurality of R^{A1}s may be the same or different. Furthermore, the plurality of R^{A1}s may be substituted on the same carbon atom or on different carbon atoms to the extent possible.

* is a bonding site to another structure, and may be bonded to any carbon atom on the alicyclic skeleton, but it is preferable that *s are respectively bonded to a carbon atom at a site represented by 1 or 2 and a carbon atom at a site represented by 3 or 4 in the following general formula (A-1′).

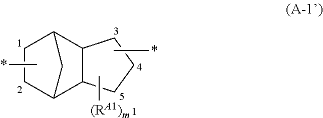

(In the formula, R^{A1}, m¹ and * are the same as those in the general formula (A-1).)

Further, from the viewpoints of the resolution of via and the adhesive strength with the plated copper, the component (A) is preferably an acid-modified vinyl group-containing resin obtained by reacting a saturated group or an unsaturated group-containing polybasic acid anhydride (a3) with a compound [hereinafter sometimes referred to as component (A′)] obtained by modifying an epoxy resin (a1) with an ethylenically unsaturated group-containing organic acid (a2). Here, “acid-modified” in the acid-modified vinyl group-containing resin means having an acidic substituent, and “vinyl group” means an ethylenically unsaturated group. Preferred aspects of the component (A) obtained from the epoxy resin (a1), the ethylenically unsaturated group-containing organic acid (a2), and the saturated group or an unsaturated group-containing polybasic acid anhydride (a3) are described below.

(Epoxy Resin (a1))

The epoxy resin (a1) is preferably an epoxy resin having two or more epoxy groups.

One type of the epoxy resin (a1) may be used alone, or two or more types thereof may be used in combination.

The epoxy resin (a1) is classified into a glycidyl ether type epoxy resin, a glycidyl amine type epoxy resin, a glycidyl ester type epoxy resin, and the like. Of these, the glycidyl ether type epoxy resin is preferred.

The epoxy resin (a1) can be classified into various epoxy resins according to a difference of the main skeleton, and can be classified into an epoxy resin having an alicyclic skeleton, a novolac type epoxy resin, a bisphenol type epoxy resin, an aralkyl type epoxy resin, other epoxy resins, and the like. Of these, the epoxy resin having an alicyclic skeleton and the novolac type epoxy resin are preferred. Note that although not particularly limited, it is preferable that none of the novolac type epoxy resin, the bisphenol type epoxy resin, the aralkyl type epoxy resin, and other epoxy resin have an alicyclic skeleton.

### —Epoxy Resin Having Alicyclic Skeleton—

The alicyclic skeleton contained in the epoxy resin having an alicyclic skeleton is explained in the same manner as the alicyclic skeleton contained in the component (A) described above, and preferred aspects are also the same.

As the epoxy resin having an alicyclic skeleton, an epoxy resin represented by the following general formula (A-2) is preferred.

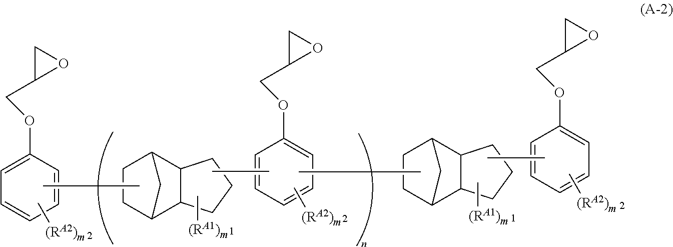

(In the formula, R^{A1} represents an alkyl group having 1 to 12 carbon atoms and may be substituted anywhere in the alicyclic skeleton. R^{A2} represents an alkyl group having 1 to 12 carbon atoms. m¹ is an integer from 0 to 6, and m² is an integer from 0 to 3. n is a number from 0 to 50.)

In the general formula (A-2), R^{A1} is the same as R^{A1} in the general formula (A-1), and preferred aspects are also the same.

Examples of the alkyl group having 1 to 12 carbon atoms represented by R^{A2} in the general formula (A-2) include a methyl group, an ethyl group, an n-propyl group, an isopropyl group, an n-butyl group, an isobutyl group, a t-butyl group, and an n-pentyl group. As the alkyl group, the alkyl group having 1 to 6 carbon atoms is preferred, the alkyl group having 1 to 3 carbon atoms is more preferred, and the methyl group is even more preferred.

In the general formula (A-2), m¹ is the same as m¹ in the general formula (A-1), and preferred aspects are also the same.

In the general formula (A-2), m² is the integer from 0 to 3, preferably 0 or 1, and more preferably 0.

In the general formula (A-2), n represents the number of repetitions of a structural unit in parentheses, and is the number from 0 to 50. Typically, the epoxy resins are mixtures of resins with different numbers of repetitions of the structural unit in the parentheses, and thus in this case, n is expressed as an average value of the mixture. A number from 0 to 30 is preferred for n.

As the epoxy resin having an alicyclic skeleton, a commercially available product may be used, and examples thereof include XD-1000 (trade name, manufactured by Nippon Kayaku Co., Ltd.) and EPICLON (registered trademark) HP-7200 (trade name, manufactured by DIC Corporation).

### —Novolac Type Epoxy Resin—

Examples of the novolac type epoxy resin include: bisphenol novolac type epoxy resins such as bisphenol A novolac type epoxy resins, bisphenol F novolac type epoxy resins, and bisphenol S novolac type epoxy resins; phenol novolac type epoxy resins; cresol novolac type epoxy resins; biphenyl novolac type epoxy resins; and naphthol novolac type epoxy resins. The novolac type epoxy resins are not particularly limited, but the cresol novolac type epoxy resins are preferred.

Further, as the novolac type epoxy resin, an epoxy resin having a structural unit represented by the following general formula (A-3) is preferred.

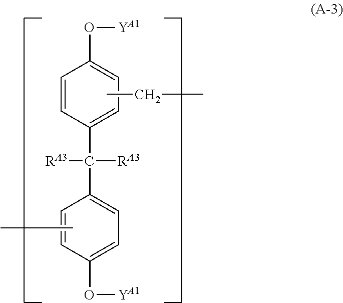

(In the formula, R^{A3} represents a hydrogen atom or a methyl group, and each Y^{A1} independently represents a hydrogen atom or a glycidyl group. Two R^{A3}s may be the same or different. At least one of two Y^{A1}s represents the glycidyl group.)

From the viewpoints of the resolution of via and the adhesive strength with the plated copper, all R^{A3}s are preferably hydrogen atoms. Further, from the same viewpoints, all Y^{A1}s are preferably glycidyl groups.

The number of structural units in the epoxy resin (a1) having the structural unit represented by the general formula (A-3) is 1 or more, preferably 10 to 100, more preferably 15 to 80, and even more preferably 15 to 70. When the number of structural units is within the above range, the adhesive strength with the plated copper, the heat resistance, and the insulation reliability tend to be improved.

An epoxy resin in which all R^{A3}s are hydrogen atoms and all Y^{A1}s are glycidyl groups in the general formula (A-3) is commercially available as EXA-7376 series (trade name, manufactured by DIC Corporation). Further, an epoxy resin in which all R^{A3}s are methyl groups and all Y^{A1}s are glycidyl groups is commercially available as EPON SU8 series (trade name, manufactured by Mitsubishi Chemical Corporation).

Examples of the bisphenol type epoxy resins include bisphenol A type epoxy resins, bisphenol F type epoxy resins, bisphenol S type epoxy resins, and 3,3′,5,5′-tetramethyl-4,4′-diglycidyloxydiphenylmethane.

Examples of the aralkyl type epoxy resin include phenol aralkyl type epoxy resins, biphenyl aralkyl type epoxy resins, and naphthol aralkyl type epoxy resins.

Examples of the other epoxy resins include stilbene type epoxy resins, naphthalene skeleton-containing epoxy resins, biphenyl type epoxy resins, dihydroanthracene type epoxy resins, cyclohexane dimethanol type epoxy resins, trimethylol type epoxy resins, alicyclic epoxy resins, aliphatic chain epoxy resins, heterocyclic epoxy resins, spiro ring-containing epoxy resins, and rubber-modified epoxy resins.

(Ethylenically Unsaturated Group-Containing Organic Acid (a2))

The ethylenically unsaturated group-containing organic acid (a2) is preferably an ethylenically unsaturated group-containing monocarboxylic acid.

The ethylenically unsaturated group contained in the component (a2) can be the same as those exemplified as the ethylenically unsaturated group contained in the component (A).

Examples of the component (a2) include: acrylic acid; a dimer of acrylic acid; acrylic acid derivatives such as methacrylic acid, β-furfurylacrylic acid, β-styrylacrylic acid, cinnamic acid, crotonic acid, and α-cyanocinnamic acid; half-ester compounds which are reaction products of hydroxyl group-containing acrylates and dibasic acid anhydrides; and half-ester compounds which are reaction products of vinyl group-containing monoglycidyl ethers or vinyl group-containing monoglycidyl esters and dibasic acid anhydrides.

One type of the component (a2) may be used alone, or two or more types thereof may be used in combination.

The half-ester compound is obtained by reacting one or more ethylenically unsaturated group-containing compounds selected from the group consisting of hydroxyl group-containing acrylates, vinyl group-containing monoglycidyl ethers, and vinyl group-containing monoglycidyl esters with the dibasic acid anhydride. The reaction is preferably carried out by reacting the ethylenically unsaturated group-containing compound with the dibasic acid anhydride in equimolar amounts.

Examples of the hydroxyl group-containing acrylates used in the synthesis of the half-ester compounds include hydroxyethyl (meth)acrylate, hydroxypropyl (meth)acrylate, hydroxybutyl (meth)acrylate, polyethylene glycol mono(meth)acrylate, trimethylolpropane di(meth)acrylate, pentaerythritol tri(meth)acrylate, and dipentaerythritol penta(meth)acrylate. Examples of the vinyl group-containing monoglycidyl ethers include glycidyl (meth)acrylate.

The dibasic acid anhydride used in the synthesis of the half ester compound may contain a saturated group or an unsaturated group. Examples of the dibasic acid anhydrides include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

In the reaction between the component (a1) and the component (a2), an amount of the component (a2) used with respect to 1 equivalent of epoxy groups in the component (a1) is preferably 0.6 to 1.05 equivalents, more preferably 0.7 to 1.02 equivalents, and even more preferably 0.8 to 1.0 equivalents. By reacting the component (a1) and the component (a2) in the above ratio, the photopolymerizability of the component (A) tends to be improved, and the resolution of via of the resulting photosensitive resin composition tends to be improved.

The component (a1) and the component (a2) are preferably dissolved in an organic solvent and reacted.

Examples of the organic solvent include: ketones such as methyl ethyl ketone and cyclohexanone; aromatic hydrocarbons such as toluene, xylene, and tetramethylbenzene; glycol ether-based compounds such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. One type of the organic solvent may be used alone, or two or more types thereof may be used in combination.

In the reaction between the component (a1) and the component (a2), a catalyst for promoting the reaction is preferably used. Examples of the catalyst include: amine-based catalysts such as triethylamine and benzylmethylamine; quaternary ammonium salt catalysts such as methyltriethylammonium chloride, benzyltrimethylammonium chloride, benzyltrimethylammonium bromide, and benzyltrimethylammonium iodide; and phosphine-based catalysts such as triphenylphosphine. Of these, the phosphine-based catalysts are preferred, and triphenylphosphine is more preferred. One type of the catalyst may be used alone, or two or more types thereof may be used in combination.

When the catalyst is used, an amount of the catalyst used is preferably 0.01 to 10 parts by mass, more preferably 0.05 to 5 parts by mass, and even more preferably 0.1 to 2 parts by mass based on 100 parts by mass of the total of the components (a1) and (a2), from the viewpoint of obtaining an appropriate reaction rate.

In the reaction between the component (a1) and the component (a2), a polymerization inhibitor is preferably used for the purpose of preventing polymerization during the reaction. Examples of the polymerization inhibitor include hydroquinone, methylhydroquinone, hydroquinone monomethyl ether, catechol, and pyrogallol. One type of the polymerization inhibitor may be used alone, or two or more types thereof may be used in combination.

When the polymerization inhibitor is used, an amount of the polymerization inhibitor used is preferably 0.01 to 1 part by mass, more preferably 0.02 to 0.8 parts by mass, and even more preferably 0.1 to 0.5 parts by mass based on 100 parts by mass of the total of the components (a1) and (a2).

A reaction temperature between the component (a1) and the component (a2) is preferably 60 to 150° C., more preferably 80 to 120° C., and even more preferably 90 to 110° C., from the viewpoint of allowing the reaction to proceed homogeneously while ensuring sufficient reactivity.

As described above, when an ethylenically unsaturated group-containing monocarboxylic acid is used as the component (a2), the component (A′) obtained by reacting the component (a1) and the component (a2) has a hydroxyl group formed by a ring-opening addition reaction between the epoxy group of the component (a1) and the carboxy group of the component (a2). Subsequently, by further reacting the component (A′) with the component (a3), an acid-modified vinyl group-containing resin can be obtained in which hydroxyl groups (including hydroxyl groups originally present in the component (a1)) of the component (A′) and acid anhydride groups of the component (a3) are half-esterified.

(Polybasic Acid Anhydride (a3))

The component (a3) may contain a saturated group or an unsaturated group. Examples of the component (a3) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Of these, tetrahydrophthalic anhydride is preferred from the viewpoint of the resolution of via. One type of the component (a3) may be used alone, or two or more types thereof may be used in combination.

In the reaction between the component (A′) and the component (a3), for example, the acid value of the acid-modified vinyl group-containing resin can be adjusted by reacting 0.1 to 1.0 equivalents of the component (a3) with respect to 1 equivalent of the hydroxyl group in the component (A′).

A reaction temperature between the component (A′) and the component (a3) is preferably 50 to 150° C., more preferably 60 to 120° C., and even more preferably 70 to 100° C., from the viewpoint of allowing the reaction to proceed homogeneously while ensuring sufficient reactivity.

The content of the component (A) in the photosensitive resin composition of the present embodiment is not particularly limited, but from the viewpoints of the heat resistance, the relative dielectric constant, and chemical resistance, it is preferably 10 to 80% by mass, more preferably 15 to 75% by mass, even more preferably 25 to 70% by mass, particularly preferably 35 to 70% by mass, and most preferably 45 to 70% by mass, based on a total amount of the resin components in the photosensitive resin composition.

### <Thermosetting Resin (B)>

The component (B) is a thermosetting resin. The component (B) does not include the component (A).

When the photosensitive resin composition of the present embodiment contains the thermosetting resin (B), the heat resistance tends to be improved in addition to improvement of the adhesive strength with the plated copper and the insulation reliability.

Examples of the thermosetting resin include epoxy resins, phenolic resins, unsaturated imide resins, cyanate resins, isocyanate resins, benzoxazine resins, oxetane resins, amino resins, unsaturated polyester resins, allyl resins, dicyclopentadiene resins, silicone resins, triazine resins, and melamine resins. In addition, the thermosetting resin is not particularly limited to these, and any known thermosetting resin can be used. Of these, the epoxy resins are preferred from the viewpoints of the adhesive strength with the plated copper, the insulation reliability, and the heat resistance.

One type of the component (B) may be used alone, or two or more types thereof may be used in combination.

The epoxy resin is preferably an epoxy resin having two or more epoxy groups. The epoxy resins are classified into glycidyl ether type epoxy resins, glycidyl amine type epoxy resins, glycidyl ester type epoxy resins, and the like. Of these, the glycidyl ether type epoxy resins are preferred.

The epoxy resins are also classified into various epoxy resins according to the difference of the main skeleton, and each type of the epoxy resins is further classified as follows. Specifically, the epoxy resins are classified into: bisphenol-based epoxy resins such as bisphenol A type epoxy resins, bisphenol F type epoxy resins, and bisphenol S type epoxy resins; bisphenol-based novolac type epoxy resins such as bisphenol A novolac type epoxy resins and bisphenol F novolac type epoxy resins; novolac type epoxy resins other than the bisphenol-based novolac type epoxy resins, such as phenol novolac type epoxy resins, cresol novolac type epoxy resins, and biphenyl novolac type epoxy resins; phenol aralkyl type epoxy resins; stilbene type epoxy resins; naphthalene skeleton-containing epoxy resins such as naphthol novolac type epoxy resins, naphthol type epoxy resins, naphthol aralkyl type epoxy resins, and naphthylene ether type epoxy resins; biphenyl type epoxy resins; biphenyl aralkyl type epoxy resins; xylylene type epoxy resins; dihydroanthracene type epoxy resins; alicyclic epoxy resins such as saturated dicyclopentadiene type epoxy resins; heterocyclic epoxy resins; spiro ring-containing epoxy resins; cyclohexane dimethanol type epoxy resins; trimethylol type epoxy resins; aliphatic chain epoxy resins; rubber-modified epoxy resins; and the like.

Of these, particularly from the viewpoints of the heat resistance, the electrical insulation reliability, developability, and the adhesive strength with the plated copper, the epoxy resin preferably contains at least one selected from the group consisting of the bisphenol-based epoxy resin, the naphthalene skeleton-containing epoxy resin, and the biphenylaralkyl type epoxy resin, and more preferably contains at least one selected from the group consisting of the naphthalene skeleton-containing epoxy resin and the biphenylaralkyl-type epoxy resin.

An equivalent ratio [epoxy group/acidic substituent] of the acidic substituent of the component (A) and the epoxy group of the component (B) in the photosensitive resin composition of the present embodiment is not particularly limited, but from the viewpoints of the insulation reliability, the relative dielectric constant, the heat resistance, and the adhesive strength with the plated copper, it is preferably 0.5 to 6.0, more preferably 0.7 to 4.0, even more preferably 0.8 to 2.0, and particularly preferably 0.9 to 1.8.

The content of the component (B) in the photosensitive resin composition of the present embodiment is not particularly limited, but from the viewpoints of the insulation reliability, the relative dielectric constant, the heat resistance, and the adhesive strength with the plated copper, it is preferably 1 to 50% by mass, more preferably 5 to 30% by mass, even more preferably 10 to 25% by mass, and most preferably 15 to 25% by mass, based on the total amount of the resin components in the photosensitive resin composition.

### <Crosslinking Agent (C)>

The photosensitive resin composition of the present embodiment preferably further contains a crosslinking agent as the component (C). The crosslinking agent is preferably a crosslinking agent having two or more ethylenically unsaturated groups and no acidic substituents. The crosslinking agent reacts with the ethylenically unsaturated groups of the component (A) to increase a crosslinking density of the photosensitive resin film after curing. Therefore, the photosensitive resin composition of the present embodiment tends to have further improved heat resistance and relative dielectric constant by containing the crosslinking agent. One type of the component (C) may be used alone, or two or more types thereof may be used in combination.

Examples of the component (C) include a bifunctional monomer having two ethylenically unsaturated groups, and a polyfunctional monomer having three or more ethylenically unsaturated groups. The component (C) preferably contains the polyfunctional monomer.

Examples of the ethylenically unsaturated groups contained in the component (C) include the same ethylenically unsaturated groups as those contained in the component (A), and the preferred ones are also the same.

Examples of the bifunctional monomer include: aliphatic di(meth)acrylates such as trimethylolpropane di(meth)acrylate, polypropylene glycol di(meth)acrylate, and polyethylene glycol di(meth)acrylate; di(meth)acrylates having an alicyclic skeleton such as dicyclopentadiene di(meth)acrylate and tricyclodecane dimethanol di(meth)acrylate; and aromatic di(meth)acrylates such as 2,2-bis(4-(meth)acryloxypolyethoxypolypropoxyphenyl)propane and bisphenol A diglycidyl ether di(meth)acrylate.

Of these, from the viewpoint of obtaining a lower relative dielectric constant, di(meth)acrylates having an alicyclic skeleton are preferred, and tricyclodecane dimethanol diacrylate is more preferred.

Examples of the polyfunctional monomer include: (meth)acrylate compounds having a skeleton derived from trimethylolpropane, such as trimethylolpropane tri(meth)acrylate; (meth)acrylate compounds having a skeleton derived from tetramethylolmethane, such as tetramethylolmethane tri(meth)acrylate and tetramethylolmethane tetra(meth)acrylate; (meth)acrylate compounds having a skeleton derived from pentaerythritol, such as pentaerythritol tri(meth)acrylate and pentaerythritol tetra(meth)acrylate; (meth)acrylate compounds having a skeleton derived from dipentaerythritol, such as dipentaerythritol penta(meth)acrylate and dipentaerythritol hexa(meth)acrylate; (meth)acrylate compounds having a skeleton derived from ditrimethylolpropane, such as ditrimethylolpropane tetra(meth)acrylate; and (meth)acrylate compounds having a skeleton derived from diglycerin. Of these, from the viewpoint of the resolution of via and the adhesive strength with the plated copper, the (meth)acrylate compounds having a skeleton derived from trimethylolpropane are preferred, and trimethylolpropane tri(meth)acrylate is more preferred.

Here, the “(meth)acrylate compound having a skeleton derived from XXX” (where XXX is a name of the compound) refers to an esterification product of XXX and (meth)acrylic acid, and the esterification product also includes compounds modified with an alkyleneoxy group.

When the photosensitive resin composition of the present embodiment contains a crosslinking agent (C), the content of the crosslinking agent (C) is not particularly limited, but from the viewpoints of the heat resistance and the relative dielectric constant, it is preferably 1 to 85 parts by mass, more preferably 5 to 70 parts by mass, even more preferably 10 to 50 parts by mass, and particularly preferably 10 to 40 parts by mass based on 100 parts by mass of the component (A).

### <Elastomer (D)>

The photosensitive resin composition of the present embodiment preferably further contains an elastomer as component (D). When the photosensitive resin composition of the present embodiment contains an elastomer (D), the adhesive strength with the plated copper tends to be further improved. In addition, by containing the elastomer (D) in the photosensitive resin composition of the present embodiment, an effect of suppressing “reduction in flexibility and the adhesive strength with the plated copper” caused by distortion (internal stress) that may occur due to cure shrinkage of the component (A) tends to be obtained.

One type of the elastomer (D) may be used alone, or two or more types thereof may be used in combination.

The elastomer (D) may have a reactive functional group at a molecular end or in a molecular chain.

Examples of the reactive functional group include acid anhydride groups, epoxy groups, hydroxyl groups, carboxyl groups, amino groups, amide groups, isocyanato groups, acrylic groups, methacrylic groups, and vinyl groups. Of these, from the viewpoint of the resolution of via and the adhesive strength with the plated copper, acid anhydride groups, epoxy groups, hydroxyl groups, carboxyl groups, amino groups, and amide groups are preferred, acid anhydride groups and epoxy groups are more preferred, and acid anhydride groups are even more preferred.

The acid anhydride group is preferably an acid anhydride group derived from phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, dimethylglutaric anhydride, diethylglutaric anhydride, succinic anhydride, methylhexahydrophthalic anhydride, methyltetrahydrophthalic anhydride, or the like, and is more preferably an acid anhydride group derived from maleic anhydride.

When the elastomer (D) has acid anhydride groups, from the viewpoints of the resolution of via and the relative dielectric constant, the number of acid anhydride groups contained in one molecule is preferably 1 to 10, more preferably 3 to 10, and even more preferably 6 to 10.

The photosensitive resin composition of the present embodiment preferably contains, as the elastomer (D), an elastomer having an ethylenically unsaturated group and an acidic substituent.

The acidic substituent and the ethylenically unsaturated group can be the same as the acidic substituent and the ethylenically unsaturated group contained in the component (A). Of these, the elastomer (D) preferably has the acid anhydride group described above as the acidic substituent, and 1,2-vinyl group described below as the ethylenically unsaturated group.

Examples of the elastomer (D) include polybutadiene-based elastomers, polyester-based elastomers, styrene-based elastomers, olefin-based elastomers, urethane-based elastomers, polyamide-based elastomers, acrylic elastomers, silicone-based elastomers, and derivatives of these elastomers. Of these, polybutadiene-based elastomers are preferred from the viewpoints of improving the adhesive strength with the plated copper and further improving compatibility and solubility with the resin components.

Suitable examples of the polybutadiene-based elastomers include those containing 1,2-vinyl groups and having 1,4-trans structural units and 1,4-cis structural units.

As mentioned above, from the viewpoint of the resolution of via, the polybutadiene-based elastomer is preferably a polybutadiene-based elastomer having an acid anhydride group and modified with an acid anhydride, and more preferably a polybutadiene-based elastomer having an acid anhydride group derived from maleic anhydride.

The polybutadiene-based elastomers are commercially available, and specific examples thereof include “POLYVEST (registered trademark) MA75” and “POLYVEST (registered trademark) EP MA120” (all trade names, manufactured by Evonik), “Ricon (registered trademark) 100”, “Ricon (registered trademark) 130MA8”, “Ricon (registered trademark) 131MA5”, “Ricon (registered trademark) 131MA17”, and “Ricon (registered trademark) 184MA6” (all trade names, manufactured by Cray Valley).

From the viewpoint of the adhesive strength with the plated copper, the polybutadiene-based elastomer may be polybutadiene having an epoxy group [hereinafter, may be referred to as epoxidized polybutadiene].

From the viewpoints of the adhesive strength with the plated copper and the flexibility, the epoxidized polybutadiene is preferably an epoxidized polybutadiene represented by the following general formula (D-1).

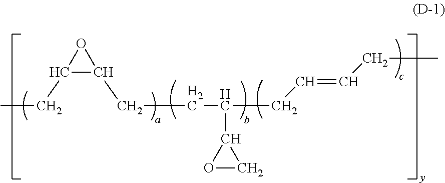

(In the formula, a, b, and c each represent a ratio of structural units in parentheses, a is 0.05 to 0.40, b is 0.02 to 0.30, c is 0.30 to 0.80, and further, a+b+c=1.00 and (a+c)>b are satisfied. y represents the number of structural units in square brackets and is an integer of 10 to 250.)

In the general formula (D-1), the structural units in the square brackets may be bonded in any order. In other words, the structural unit shown on the left, the structural unit shown in the center, and the structural unit shown on the right may be interchanged, and if they are respectively represented as (a), (b), and (c), various bond orders are possible, such as -[(a)-(b)-(c)]-[(a)-(b)-(c)-]-, -[(a)-(c)-(b)]-[(a)-(c)-(b)-]-, -[(b)-(a)-(c)]-[(b)-(a)-(c)-]-, -[(a)-(b)-(c)]-[(c)-(b)-(a)-]-, -[(a)-(b)-(a)]-[(c)-(b)-(c)-]-, and -[(c)-(b)-(c)]-[(b)-(a)-(a)-]-.

From the viewpoints of the adhesive strength with the plated copper and the flexibility, a is preferably 0.10 to 0.30, b is preferably 0.10 to 0.30, and c is preferably 0.40 to 0.80. In addition, from the same viewpoints, y is preferably an integer of 30 to 180.

Examples of the polyester-based elastomers include those obtained by polycondensation of dicarboxylic acids or their derivatives with diol compounds or their derivatives.

Examples of the dicarboxylic acids include: aromatic dicarboxylic acids such as terephthalic acid, isophthalic acid, and naphthalenedicarboxylic acid, and aromatic dicarboxylic acids in which hydrogen atoms of the aromatic nuclei are substituted with methyl groups, ethyl groups, phenyl groups, and the like; aliphatic dicarboxylic acids having 2 to 20 carbon atoms, such as adipic acid, sebacic acid, and dodecanedicarboxylic acid; and alicyclic dicarboxylic acids such as cyclohexanedicarboxylic acid.

Examples of the diol compounds include: aliphatic diols such as ethylene glycol, 1,3-propanediol, 1,4-butanediol, 1,6-hexanediol, and 1,10-decanediol; alicyclic diols such as 1,4-cyclohexanediol; and aromatic diols such as bisphenol A, bis(4-hydroxyphenyl)methane, bis(4-hydroxy-3-methylphenyl)propane, and resorcin.

Further, suitable examples of the polyester-based elastomers include multiblock copolymers in which an aromatic polyester (for example, polybutylene terephthalate) portion serves as a hard segment component and an aliphatic polyester (for example, polytetramethylene glycol) portion serves as a soft segment component. The multiblock copolymers are available in various grades depending on the types, ratios, and molecular weights of the hard segment and the soft segment.

A number average molecular weight of the elastomer (D) is not particularly limited, but is preferably 10,000 to 80,000, may be 20,000 to 70,000, may be 30,000 to 65,000, or may be 40,000 to 60,000. The number average molecular weight of the elastomer (D) is determined by being converted into standard polystyrene by gel permeation chromatography (GPC) using tetrahydrofuran as a solvent.

When the photosensitive resin composition of the present embodiment contains the elastomer (D), the content of the elastomer (D) is not particularly limited, but from the viewpoints of the heat resistance and the adhesive strength with the plated copper, it is preferably 0.5 to 15% by mass, more preferably 1 to 10% by mass, even more preferably 1 to 8% by mass, and particularly preferably 3 to 8% by mass, based on the total amount of the resin components in the photosensitive resin composition.

### <Inorganic Filler (E)>

The photosensitive resin composition of the present embodiment may further contain the inorganic filler as component (E). The component (E) does not contain the particles (X). That is, the component (E) is an inorganic filler other than the particles (X).

When the photosensitive resin composition of the present embodiment contains an inorganic filler (E), a low thermal expansion coefficient, the heat resistance, and flame retardancy tend to be further improved.

The component (E) is not particularly limited, but examples thereof include silica, alumina, titanium oxide, mica, beryllia, barium titanate, potassium titanate, strontium titanate, calcium titanate, aluminum carbonate, aluminum hydroxide, aluminum silicate, calcium silicate, magnesium silicate, silicon nitride, boron nitride, clay (calcined clay and the like), molybdic acid compounds such as zinc molybdate, aluminum borate, and silicon carbide. One type of the component (E) may be used alone, or two or more types thereof may be used in combination. Of these, from the viewpoints of the thermal expansion coefficient, the heat resistance, and the flame retardancy, as the inorganic filler, silica, alumina, and mica are preferred, silica and alumina are more preferred, and silica is even more preferred. Examples of the silica include crushed silica, fumed silica, and fused silica (fused spherical silica).

The volume average particle diameter of the component (E) is not particularly limited, but is preferably 0.01 to 20 μm, more preferably 0.1 to 10 μm, even more preferably 0.2 to 1 μm, and particularly preferably 0.3 to 0.8 μm.

### (Content of Component (E))

When the photosensitive resin composition of the present embodiment contains the component (E), from the viewpoint of not impairing an effect of the particles (X), the content of the component (E) is preferably 20% by mass or less, more preferably 15% by mass or less, even more preferably 10% by mass or less, and particularly preferably 5% by mass or less, based on the total solid content of the photosensitive resin composition. The photosensitive resin composition of the present embodiment does not need to contain the component (E).

### <Organic Filler (F)>

The photosensitive resin composition of the present embodiment may further contain an organic filler as component (F). The component (F) does not contain the particles (X). That is, the component (F) is an organic filler other than the particles (X).

When the photosensitive resin composition of the present embodiment contains an organic filler (F), specific gravities of the photosensitive resin composition and the photosensitive resin film tend to be reduced, and the relative dielectric constant also tends to be further reduced depending on the material.

The component (F) preferably contains resin particles formed from at least one selected from the group consisting of resins having fluorine atoms, polyethylene, polypropylene, polystyrene, polyphenylene ether, and silicone. Of these, from the viewpoint of an effect of reducing the relative dielectric constant, the component (F) preferably contains resin particles formed from the resin having fluorine atoms, and more preferably contains resin particles formed from a polytetrafluoroethylene (PTFE) resin.

The volume average particle diameter of the resin particles is not particularly limited, but is preferably 20 to 1,000 nm, more preferably 30 to 800 nm, even more preferably 50 to 500 nm, and particularly preferably 100 to 300 nm. A method for measuring the volume average particle diameter is as described above.

When the photosensitive resin composition of the present embodiment contains the organic filler (F), from the viewpoint of not impairing the effect of the particles (X), the content of the organic filler (F) is preferably 20% by mass or less, more preferably 10% by mass or less, and even more preferably 5% by mass or less, based on the total amount of the resin components in the photosensitive resin composition. The photosensitive resin composition of the present embodiment does not need to contain the component (F).

### <Curing Agent (G)>

The photosensitive resin composition of the present embodiment preferably further contains a curing agent as component (G). When the photosensitive resin composition of the present embodiment contains a curing agent (G), the heat resistance, the relative dielectric constant, and the like tend to be further improved.

One type of the curing agent (G) may be used alone, or two or more types thereof may be used in combination.

As the curing agent (G), a curing agent for the thermosetting resin (B) may be used. For example, when the thermosetting resin (B) is the epoxy resin, an epoxy resin curing agent is preferably used, and examples of the epoxy resin curing agent include: guanamines such as acetoguanamine and benzoguanamine; polyamines such as diaminodiphenylmethane, m-phenylenediamine, m-xylylenediamine, diaminodiphenylsulfone, dicyandiamide, urea, urea derivatives, melamine, and polybasic hydrazides; organic acid salts and/or epoxy adducts of these; amine complexes of boron trifluoride; triazine derivatives such as ethyldiamino-S-triazine, 2,4-diamino-S-triazine, and 2,4-diamino-6-xylyl-S-triazine; and polyphenols such as polyvinylphenol, polyvinylphenol bromide, phenol novolac, alkylphenol novolac, and triazine ring-containing phenol novolac resins.

The polyphenol may be a modified polyphenol modified with, for example, melamine, benzoguanamine, or the like. Hydroxyl equivalent of the polyphenol is not particularly limited, but is preferably 40 to 300 g/eq, or may be 40 to 250 g/eq, 60 to 200 g/eq, 80 to 160 g/eq, or 100 to 140 g/eq. Here, the hydroxyl equivalent (g/eq) can be determined by titration using an acetylation method with acetic anhydride.

When the photosensitive resin composition of the present embodiment contains the curing agent (G), the content of the curing agent (G) is not particularly limited, but from the viewpoint of further improving the heat resistance and the relative dielectric constant, the content is preferably 0.01 to 10% by mass, more preferably 0.05 to 5% by mass, and even more preferably 0.1 to 1% by mass, based on the total amount of the resin components in the photosensitive resin composition.

### <Curing Accelerator (H)>

The photosensitive resin composition of the present embodiment preferably further contains a curing accelerator as component (H). When the photosensitive resin composition of the present embodiment contains a curing accelerator (H), the heat resistance, the relative dielectric constant, and the like tend to be further improved.

One type of the curing accelerator (H) may be used alone, or two or more types thereof may be used in combination.

Examples of the curing accelerator (H) include imidazole-based compounds such as 2-methylimidazole, 2-ethyl-4-methylimidazole, 1-benzyl-2-methylimidazole, 2-phenylimidazole, 2-phenyl-1-benzyl-1H-imidazole, 2-phenyl-4-methyl-5-hydroxymethylimidazole, and isocyanate masked imidazole (addition reaction product of hexamethylene diisocyanate resin and 2-ethyl-4-methylimidazole); tertiary amines such as trimethylamine, N,N-dimethyloctylamine, N-benzyldimethylamine, pyridine, N-methylmorpholine, hexa(N-methyl)melamine, 2,4,6-tris(dimethylaminophenol), tetramethylguanidine, and m-aminophenol; organic phosphines such as tributylphosphine, triphenylphosphine, and tris-2-cyanoethylphosphine; phosphonium salts such as tri-n-butyl(2,5-dihydroxyphenyl)phosphonium bromide and hexadecyltributylphosphonium chloride; quaternary ammonium salts such as benzyltrimethylammonium chloride and phenyltributylammonium chloride; the above-mentioned polybasic acid anhydrides; diphenyliodonium tetrafluoroborate; triphenylsulfonium hexafluoroantimonate; and 2,4,6-triphenylthiopyrylium hexafluorophosphate.

Of these, the imidazole-based compounds are preferred from the viewpoint of obtaining an excellent curing action.

When the photosensitive resin composition of the present embodiment contains the curing accelerator (H), the content of the curing accelerator (H) is not particularly limited, but from the viewpoint of further improving the heat resistance and the relative dielectric constant, it is preferably 0.01 to 10% by mass, more preferably 0.05 to 5% by mass, and even more preferably 0.1 to 2% by mass, based on the total amount of the resin components in the photosensitive resin composition.

### <Photopolymerization Initiator (I)>

The photosensitive resin composition of the present embodiment preferably further contains a photopolymerization initiator as component (I). When the photosensitive resin composition of the present embodiment contains a photopolymerization initiator (I), the resolution of via tends to be further improved.

One type of the photopolymerization initiator (I) may be used alone, or two or more types thereof may be used in combination. From the viewpoint of the resolution of via, the photosensitive resin composition of the present embodiment preferably contains two or more types of the component (I).

The photopolymerization initiator (I) is not particularly limited as long as it can photopolymerize the ethylenically unsaturated group, and can be appropriately selected from commonly used photopolymerization initiators.

Examples of the photopolymerization initiator (I) include: benzoin-based compounds such as benzoin, benzoin methyl ether, and benzoin isopropyl ether; acetophenone-based compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-1-butanone, 2-[4-(methylthio)benzoyl]-2-(4-morpholinyl)propane, and N,N-dimethylaminoacetophenone; anthraquinone-based compounds such as 2-methylanthraquinone, 2-ethylanthraquinone, 2-tert-butylanthraquinone, 1-chloroanthraquinone, 2-amylanthraquinone, and 2-aminoanthraquinone; ketal-based compounds such as acetophenone dimethyl ketal and benzyl dimethyl ketal; acridine-based compounds such as 9-phenylacridine and 1,7-bis(9,9′-acridinyl)heptane; acylphosphine oxide-based compounds such as bis(2,4,6-trimethylbenzoyl)phenylphosphine oxide; and oxime ester-based compounds such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(0-acetyloxime), and 1-phenyl-1,2-propanedione-2-[O-(ethoxycarbonyl)oxime].

Of these, the oxime ester-based compounds and the acylphosphine oxide-based compounds are preferred, and 1-[9-ethyl-6-(2-methylbenzoyl)-9H-carbazol-3-yl]ethanone 1-(O-acetyloxime) and bis(2,4,6-trimethylbenzoyl)phenylphosphine oxide are more preferred. The oxime ester-based compounds have an advantage of improving photocurability, and the acylphosphine oxide-based compounds have an advantage of improving degree of cure at a bottom of a cured product obtained by curing the photosensitive resin film, and suppressing undercut. By using the oxime ester-based compound and the acylphosphine oxide-based compound in combination, the resolution of via tends to be further improved.

When the photosensitive resin composition of the present embodiment contains the photopolymerization initiator (I), the content of the photopolymerization initiator (I) is not particularly limited, but is preferably 0.01 to 20% by mass, more preferably 0.05 to 10% by mass, even more preferably 0.05 to 3% by mass, and particularly preferably 0.05 to 1.0% by mass, based on the total amount of the resin components in the photosensitive resin composition. When the content of the photopolymerization initiator (I) is the lower limit or more, elution of an exposed portion during development tends to be reduced, and when it is the upper limit or less, the heat resistance tends to be improved.

### <(J) Photosensitizer>

The photosensitive resin composition of the present embodiment may contain a photosensitizer as component (J) as necessary.

One type of the photosensitizer (J) may be used alone, or two or more types thereof may be used in combination. From the viewpoint of the resolution of via, the photosensitive resin composition of the present embodiment may contain two or more types of the component (J).

Examples of the photosensitizer (J) include: thioxanthone-based compounds such as 2,4-dimethylthioxanthone, 2,4-diethylthioxanthone, 2-chlorothioxanthone, and 2,4-diisopropylthioxanthone; tertiary amines such as trialkylamines and triethanolamine; dialkylaminobenzoic acid alkyl esters such as ethyl N,N-dimethylaminobenzoate and amyl N,N-dimethylaminobenzoate; bis(dialkylamino)benzophenones such as 4,4′-bis(dimethylamino)benzophenone and 4,4′-bis(diethylamino)benzophenone; phosphine-based compounds such as triphenylphosphine; toluidine compounds such as N,N-dimethyltoluidine; anthracene-based compounds such as 9,10-dimethoxyanthracene, 2-ethyl-9,10-dimethoxyanthracene, and 2-ethyl-9,10-diethoxyanthracene; perylene-based compounds; and coumarin-based compounds.

As the photosensitizer (J), from the viewpoint of improving the resolution of via and the shape of the via, bis(dialkylamino)benzophenone is preferred, and 4,4′-bis(diethylamino)benzophenone is more preferred.

When the photosensitive resin composition of the present embodiment contains photosensitizer (J), the content of photosensitizer (J) is not particularly limited, but is preferably 0.01 to 5% by mass, more preferably 0.05 to 3% by mass, even more preferably 0.1 to 1.5% by mass, and particularly preferably 0.1 to 1.0% by mass, based on the total amount of the resin components in the photosensitive resin composition. When the content of photosensitizer (J) is the lower limit or more, the degree of cure of the bottom of the cured product obtained by curing the photosensitive resin film tends to be sufficiently high, and when the content is the upper limit or less, the degree of cure of the bottom of the cured product tends to be appropriately low.

### <Additives (K)>

The photosensitive resin composition of the present embodiment may contain various known and commonly used additives, as necessary, such as pigments such as phthalocyanine blue, phthalocyanine green, iodine green, diazo yellow, crystal violet, titanium oxide, carbon black, and naphthalene black; adhesion aids such as melamine; foam stabilizers such as silicone compounds; polymerization inhibitors; thickeners; and flame retardants.

The content of these additives (K) may be adjusted appropriately depending on various purposes, but is preferably 0.01 to 5% by mass, and may be 0.05 to 3% by mass or 0.1 to 1% by mass, based on the total amount of the resin components in the photosensitive resin composition.

### <Diluent>

The photosensitive resin composition of the present embodiment may contain the diluent as necessary. As the diluent, the organic solvent or the like can be used. Examples of the organic solvent include: ketones such as methyl ethyl ketone and cyclohexanone; aromatic hydrocarbons such as toluene, xylene, and tetramethylbenzene; glycol ether-based compounds such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, propylene glycol monoethyl ether acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. One type of the diluent may be used alone, or two or more types thereof may be used in combination.

When the photosensitive resin composition of the present embodiment contains the diluent, the content of the diluent may be appropriately selected for the purpose of adjusting the concentration of total solids in the photosensitive resin composition to a range of preferably 40 to 90% by mass, more preferably 50 to 85% by mass, and even more preferably 60 to 80% by mass. By adjusting an amount of diluent used to within the above range, coatability of the photosensitive resin composition is improved, and a higher-definition pattern can be formed.

The photosensitive resin composition of the present embodiment can be obtained by kneading and mixing the components using a roll mill, a bead mill, or the like.

Here, the photosensitive resin composition of the present embodiment can be used in a liquid state (liquid form) or in a film state (film form).

When used in the liquid state, a coating method of the photosensitive resin composition of the present embodiment is not particularly limited, but examples of the coating method include various coating methods such as a printing method, a spin coating method, a spray coating method, a jet dispensing method, an inkjet method, and an immersion coating method. Of these, the printing method and the spin coating method are preferred from the viewpoint of forming the photosensitive layer more easily.

Further, when used in the film state, the photosensitive resin composition can be used, for example, in the form of the photosensitive resin film described later, in which case a photosensitive layer having a desired thickness can be formed by laminating it on a carrier film using a laminator or the like. Note that using in the film state is preferred because an efficiency of producing the printed wiring board is increased.

Since the photosensitive resin composition of the present embodiment is suitable for the via formation by photolithography (also referred to as the photo via formation), the present disclosure also provides a photosensitive resin composition for photo via formation containing the photosensitive resin composition of the present embodiment.

The photosensitive resin composition of the present embodiment is useful as the interlayer insulating layer of the printed wiring board, and is also useful for solder resist applications.

### [Photosensitive Resin Film]

The photosensitive resin film of the present embodiment contains the photosensitive resin composition of the present embodiment, in other words, is formed using the photosensitive resin composition of the present embodiment. The photosensitive resin film is useful as the photosensitive layer for forming the interlayer insulating layer.

The photosensitive resin film of the present embodiment is formed using the photosensitive resin composition of the present embodiment, and therefore contains 10 to 70 vol % of the particles (X). Note that the components and their contents in the photosensitive resin film are as described for the components and their contents in the photosensitive resin composition of the present embodiment.

The photosensitive resin film of the present embodiment may be a form of being provided on the carrier film.

The photosensitive resin film of the present embodiment can be formed, for example, by applying the photosensitive resin composition of the present embodiment onto the carrier film using a known coating device such as a comma coater, a bar coater, a kiss coater, a roll coater, a gravure coater, or a die coater, followed by drying.

Examples of the carrier film include polyesters such as polyethylene terephthalate and polybutylene terephthalate and polyolefins such as polypropylene and polyethylene. A thickness of the carrier film is preferably 5 to 100 μm, more preferably 10 to 60 μm, and even more preferably 15 to 45 μm.

Further, the photosensitive resin film of the present embodiment can also have a protective film provided on a surface opposite to a surface in contact with the carrier film. As the protective film, a polymer film such as polyethylene or polypropylene can be used. Further, the same polymer film as the carrier film described above may be used, or a different polymer film may be used.

A coating film formed by coating the photosensitive resin composition can be dried using hot air drying, a dryer using far-infrared or near-infrared rays, or the like. A drying temperature is preferably 60 to 150° C., more preferably 70 to 120° C., and even more preferably 80 to 110° C. Further, a drying time is preferably 1 to 60 minutes, more preferably 2 to 30 minutes, and even more preferably 5 to 20 minutes. The content of remaining diluent in the photosensitive resin film after drying is preferably 3% by mass or less, more preferably 2% by mass or less, and even more preferably 1% by mass or less, from the viewpoint of avoiding diffusion of the diluent in the production process of the printed wiring board.

A thickness (thickness after drying) of the photosensitive resin film (photosensitive layer) is not particularly limited, but from the viewpoint of thinning the printed wiring board, it is preferably 1 to 100 μm, more preferably 3 to 50 μm, and even more preferably 5 to 40 μm.

The photosensitive resin film of the present embodiment is excellent in the resolution of via and the adhesive strength with the plated copper, and is therefore suitable primarily as the interlayer insulating layer of the printed wiring board, but is also useful for the solder resist applications.

### [Printed Wiring Board]

The printed wiring board of the present embodiment is obtained by the production method described above, and contains the photosensitive resin composition of the present embodiment or the photosensitive resin film of the present embodiment. In other words, the printed wiring board contains the interlayer insulating layer formed using the photosensitive resin composition of the present embodiment or the photosensitive resin film of the present embodiment. The expression “contains the interlayer insulating layer” here includes a case where the interlayer insulating layer is contained as it is, and a case where the interlayer insulating layer is contained after, for example, processing such as via formation, various treatments such as the roughening treatment, wiring formation, or the like are performed on the interlayer insulating layer.

The printed wiring board of the present embodiment allows formation of fine wiring and has excellent adhesion to the plated copper, and can therefore also be used as an interposer for a semiconductor package.

### [Semiconductor Package]

The present disclosure also provides a semiconductor package including the printed wiring board of the present embodiment and a semiconductor element. The semiconductor package of the present embodiment can be produced by mounting a semiconductor element such as a semiconductor chip or a memory at a predetermined position on the printed wiring board of the present embodiment, and then sealing the semiconductor element with a sealing resin or the like.

### EXAMPLES

The present embodiment will be described in more detail below with reference to Examples, but the present disclosure is not limited to these examples. Note that the acid value and the weight average molecular weight of the component (A) were measured according to the following methods. Further, photosensitive resin compositions obtained in Examples were used to evaluate characteristics according to methods described below.

### <Method of Measuring Acid Value>

The acid value of the component (A) was calculated from an amount of potassium hydroxide solution required to neutralize the component (A).

### <Method of Measuring Weight-Average Molecular Weight>

The weight average molecular weight of the component (A) was measured using a GPC measurement device and measurement conditions described below, and a value converted using a calibration curve of the standard polystyrene was used as the weight average molecular weight. Further, the calibration curve was created using five sample sets (“PStQuick MP-H” and “PStQuick B”, manufactured by Tosoh Corporation) as the standard polystyrene.

### (GPC Measurement Device)

Device: High-speed GPC device “HCL-8320GPC”, detector is differential refractometer or UV, manufactured by Tosoh Corporation
Column: Column TSKgel SuperMultipore HZ-H (column length: 15 cm, column inner diameter: 4.6 mm), manufactured by Tosoh Corporation

### (Measurement Conditions)

Solvent: Tetrahydrofuran (THF)
Measurement temperature: 40° C.
Flow rate: 0.35 ml/min
Sample concentration: 10 mg/5 ml THE
Injection volume: 20 μl

### [1. Surface Roughness (Ra)]

In each of Examples and Comparative Examples, the surface roughness (Ra) of a prepreg surface prepared in each example was measured by a white light interference method with a high-performance non-contact three-dimensional surface roughness measurement system (Wyko NT9100, manufactured by Bruker Japan Co., Ltd.) for a surface of an evaluation laminate A after desmear treatment.

[2. Evaluation of Adhesive Strength with Plated Copper]

A vertical peel strength of an evaluation laminate B prepared in each of Examples and Comparative Examples was measured at 23° C. in accordance with JIS C6481 (1996).

### <Synthesis Example 1> Synthesis of Photopolymerizable Compound (A1) Having Ethylenically Unsaturated Group and Acidic Substituent

350 parts by mass of dicyclopentadiene type epoxy resin (“XD-1000” manufactured by Nippon Kayaku Co., Ltd., epoxy equivalent 252 g/eq, softening point 74.2° C., component (a1), the number of ring-forming carbon atoms in the alicyclic skeleton: 10), 70 parts by mass of acrylic acid (component (a2)), 0.5 parts by mass of methylhydroquinone, and 120 parts by mass of carbitol acetate were charged and reacted by heating to 90° C. and stirring, and the mixture was dissolved.

Then, the resulting solution was cooled to 60° C., 2 parts by mass of triphenylphosphine was added, and the mixture was heated to 100° C. and reacted until the acid value of the solution reached 1 mgKOH/g. To the reacted solution, 98 parts by mass of tetrahydrophthalic anhydride (component (a3)) and 85 parts by mass of carbitol acetate were added, heated to 80° C., and reacted for 6 hours.

Thereafter, the mixture was cooled to room temperature to obtain a photopolymerizable compound (A1) [acid value: 60 mg KOH/g, weight average molecular weight: 2,000] having an ethylenically unsaturated group and an acidic substituent and having a solids concentration of 73% by mass.

### <Synthesis Example 2> Synthesis of Photopolymerizable Compound (A2) Having Ethylenically Unsaturated Group and Acidic Substituent

350 parts by mass of cresol novolac epoxy resin (EOCN-104S manufactured by Nippon Kayaku Co., Ltd., component (a1)), 70 parts by mass of acrylic acid (component (a2)), 0.5 parts by mass of methyl hydroquinone, and 120 parts by mass of carbitol acetate were charged and reacted by heating to 90° C. and stirring, and the mixture was dissolved.

Then, the resulting solution was cooled to 60° C., 2 parts by mass of triphenylphosphine was added, and the mixture was heated to 100° C. and reacted until the acid value of the solution reached 1 mgKOH/g. To the reacted solution, 98 parts by mass of tetrahydrophthalic anhydride (component (a3)) and 85 parts by mass of carbitol acetate were added, heated to 80° C., and reacted for 6 hours.

Thereafter, the mixture was cooled to room temperature to obtain a photopolymerizable compound (A2) [acid value: 60 mg KOH/g, weight average molecular weight: 6,500] having an ethylenically unsaturated group and an acidic substituent and having a solids concentration of 73 mass %.

### Examples 1 to 12 and Comparative Examples 1 to 6

### (1) Production of Photosensitive Resin Composition

A composition was formulated according to formulation shown in Table 1 (unit of numerical values in the table is parts by mass, and in the case of solution, the unit is solid content equivalent) (note that the particles (X) were mixed with the component (A) in advance), and then kneaded with a three-roll mill. Thereafter, methyl ethyl ketone was added to adjust the solid content to 65% by mass to obtain a photosensitive resin composition.

### (2) Production of Photosensitive Resin Film

A polyethylene terephthalate film (manufactured by Teijin Limited, trade name “G2-16”) with a thickness of 16 μm was used as the carrier film. The photosensitive resin composition prepared in each example was applied onto the carrier film while adjusting the film thickness to 25 μm after drying, and the film was dried for 10 minutes at 100° C. using a hot air convection dryer to form a photosensitive resin film (photosensitive layer). Subsequently, a polyethylene film (manufactured by Tamapoly Co., Ltd., trade name “NF-15”) was laminated as a protective film on a surface of the photosensitive resin film (photosensitive layer) opposite to a surface in contact with the carrier film, to prepare a photosensitive resin film in which the carrier film and the protective film were laminated together.

### (Lamination Step (1))

While peeling off the protective film from the “photosensitive resin film with the carrier film and protective film laminated together” produced by the above method, lamination was performed on a copper-clad laminate substrate with a thickness of 1.0 mm using a press-type vacuum laminator (manufactured by Meiki Co., Ltd., trade name “MVLP-500”) at a pressing pressure of 0.4 MPa, a press hot plate temperature of 75° C., a vacuum time of 25 seconds, a lamination press time of 25 seconds, and an air pressure of 4 kPa or less to obtain a laminate.

The resulting laminate was exposed to light using a parallel light exposure machine (manufactured by ORC MANUFACTURING CO., LTD., trade name “EXM-1201”) with an ultra-high pressure mercury lamp as the light source at 200 mJ/cm² (wavelength 365 nm) over the entire surface. Subsequently, the laminate was exposed to light at an exposure dose of 2,000 mJ/cm² (wavelength 365 nm) using an ultraviolet exposure device, and then heated at 170° C. for 1 hour to obtain an “evaluation laminate” having a cured product formed on the copper-clad laminate substrate.

### (Photo Via Forming Step (2))

The evaluation laminate was exposed at 210 mJ/cm² (wavelength 365 nm) from above the carrier film using an i-line stepper (UX-7, manufactured by Ushio Inc.) with a step tablet and a via evaluation mask. Then, after peeling off the carrier film, development was performed for 40 seconds at 30° C. with a spray developer using a 1% by mass aqueous solution of sodium carbonate, to form vias with a size of approximately 60 μm. Images of the vias obtained by scanning electron microscope (SEM) measurement (magnification: 2,500 times) for Examples 2 and 11 are respectively shown in FIGS. 7 and 8. In FIG. 7 (Example 2), an opening diameter of a via top was 55.6 μm, and an opening diameter of a via bottom was 53.6 m. In addition, in FIG. 8 (Example 11), the opening diameter of the via top was 56.0 μm, and the opening diameter of the via bottom was 53.8 μm. In both cases, it can be seen that the resolution of via is excellent.

### (Roughening Treatment Step (3-1); Roughening Treatment Using Roughening Liquid)

Subsequently, first, 2 L of “Swelling Dip Securiganth MV” (trade name, manufactured by Atotech Japan K.K.) [sodium hydroxide concentration: 3 g/L] added with sodium hydroxide was heated to 70° C. as the swelling liquid, and the evaluation laminate was immersed in the solution for 5 minutes. Thereafter, the laminate was washed in stored water at 25° C. for 1 minute, and then washed in running water at 25° C. for 3 minutes.

Subsequently, 2 L of “Dosing Securiganth PMV” (trade name, manufactured by Atotech Japan K.K.) [sodium hydroxide concentration: 40 g/L] added with sodium hydroxide was heated to 60° C. as the roughening liquid, and the evaluation laminate was immersed in the solution for 5 minutes. Thereafter, the laminate was washed in stored pure water at 70° C. for 1 minute.

(Particle (X) Dissolving Step (3-2); Particles (X) were not Used in Comparative Examples, but this Step was Carried Out in the Same Manner as in Examples)

Subsequently, “Reduction Solution Securiganth MV” (trade name, manufactured by Atotech Japan K.K.) (total amount: 2,000 ml) to which the aqueous sulfuric acid solution was added so that a sulfuric acid concentration was 48 ml/L was heated to a temperature shown in Table 1, and then the evaluation laminate was immersed for a time shown in Table 1. Thereafter, it was washed in stored water at 25° C. for 1 minute, and then washed in running water at 25° C. for 3 minutes.

The evaluation laminate after the particle (X) dissolving step (3-2) is referred to as evaluation laminate A.

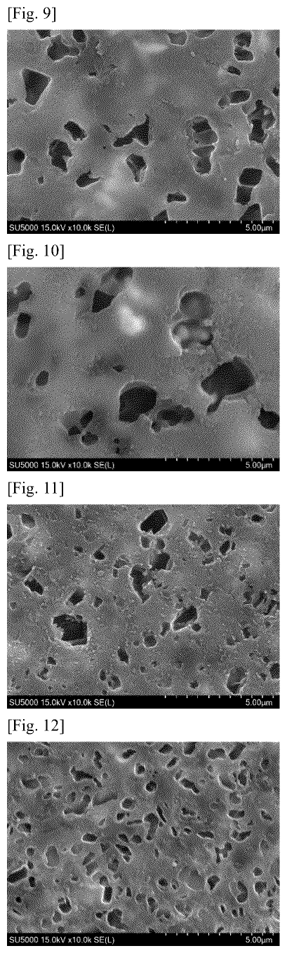

Here, in Examples 2, 5, 8, and 11 and Comparative Example 5, a surface of the evaluation laminate A was measured with a scanning electron microscope (SEM) and surface images were taken. The results are shown in FIGS. 9 to 13.

### (Circuit Pattern Forming Step (4))

Subsequently, the laminate was treated with an alkaline cleaner “Cleaner Securiganth 902” (trade name, manufactured by Atotech Japan K.K.) at 60° C. for 5 minutes, and then degreased and washed. After washing, the evaluation laminate was treated with a pre-dip liquid “Pre-dip Neoganth B” (trade name, manufactured by Atotech Japan K.K.) at 23° C. for 1 minute. Thereafter, the evaluation laminate was treated with an activator liquid “Activator Neoganth 834” (trade name, manufactured by Atotech Japan K.K.) at 35° C. for 5 minutes, and then the evaluation laminate was treated with a reducing liquid “Reducer Neoganth WA” (trade name, manufactured by Atotech Japan K.K.) at 30° C. for 5 minutes.

The evaluation laminate thus obtained was placed in a chemical copper solution (“Basic Printganth MV-TP1”, “Copper Printganth MV-TP1”, “Moderator Printganth MV-TP1”, “Stabilizer Printganth MV-TP1”, “Reducer Cu” (all trade names, manufactured by Atotech Japan K.K.) and sodium hydroxide) and electroless plating was performed until the plating thickness reached approximately 0.5 μm. After the electroless plating, an annealing treatment was performed at a temperature of 120° C. for 30 minutes to remove remaining hydrogen gas. Thereafter, copper sulfate electrolytic plating was performed, and the annealing treatment was performed at 180° C. for 60 minutes to form a conductor layer with a thickness of 25 μm. This evaluation laminate is referred to as evaluation laminate B.

Thereafter, the circuit pattern was formed on the evaluation laminate B by a semi-additive step. The measurement and evaluation results are shown in Table 1.

TABLE 1

| | | | Examples | | | | | | | | |
|---|---|---|---|---|---|---|---|---|---|---|---|
| | | | 1 | 2 | 3 | 4 | 5 | 6 | 7 | 8 | 9 |
| (A) | Photopolymerizable | A1 | 36 | | 36 | 36 | | 36 | 36 | | 36 |
| | compound having | A2 | | 36 | | | 36 | | | 36 | |
| | ethylenically | | | | | | | | | | |
| | unsaturated | | | | | | | | | | |
| | group and | | | | | | | | | | |
| | acidic substituent | | | | | | | | | | |
| (B) | Thermosetting resin | B1: YX-4000 | 12 | 12 | 12 | 12 | 12 | 12 | 12 | 12 | 12 |
| (C) | Cross-linking agent | C1: DPHA | 7.4 | 7.4 | | 7.4 | 7.4 | | 7.4 | 7.4 | |
| | | C2: TMPTA | | | 7.4 | | | 7.4 | | | 7.4 |
| (D) | Elastomer | D1: Ricon131MA17 | 4 | 4 | 4 | 4 | 4 | 4 | 4 | 4 | 4 |
| (X) | Particles that dissolve | X1: Magnesium | 46 | 46 | 46 | | | | | | |
| | 95% by mass or more | hydroxide 1 | (28) | (28) | (28) | | | | | | |
| | in aqueous sulfuric | X2: Magnesium | | | | 58 | 58 | 58 | | | |
| | acid solution having | carbonate | | | | (28) | (28) | (28) | | | |
| | concentration of 5 to | X3: Zinc oxide | | | | | | | 109 | 109 | 109 |
| | 100 ml/L under | | | | | | | | (28) | (28) | (28) |
| | conditions of 70° C. | X4: Magnesium | | | | | | | | | |
| | for 20 minutes | hydroxide 2 | | | | | | | | | |
| (E) | Inorganic filler | E1: Silica | | | | | | | | | |
| (I) | Photo- | I1: Photopoly- | 0.25 | 0.25 | 0.25 | 0.25 | 0.25 | 0.25 | 0.25 | 0.25 | 0.25 |
| | polymerization | merization | | | | | | | | | |
| | initiator | initiator 1 | | | | | | | | | |
| | | I2: Photopoly- | 0.04 | 0.04 | 0.04 | 0.04 | 0.04 | 0.04 | 0.04 | 0.04 | 0.04 |
| | | merization | | | | | | | | | |
| | | initiator 2 | | | | | | | | | |
| Conditions of | | Treatment | 50 | 50 | 50 | 70 | 70 | 70 | 50 | 50 | 50 |
| particle (X) | | temperature (° C.) | | | | | | | | | |
| dissolving step (3-2) | | Treatment time (min) | 5 | 5 | 5 | 20 | 20 | 20 | 5 | 5 | 5 |
| Evaluation | 1. Surface roughness [μm] | | 0.09 | 0.08 | 0.08 | 0.07 | 0.06 | 0.08 | 0.23 | 0.30 | 0.24 |
| results | 2. Adhesive strength with | | 0.73 | 0.68 | 0.65 | 0.7 | 0.7 | 0.65 | 0.72 | 0.76 | 0.74 |
| | plated copper [kN/m] | | | | | | | | | | |
| | | | Examples | | | Comparative Examples | | | | | |
| | | | 10 | 11 | 12 | 1 | 2 | 3 | 4 | 5 | 6 |
| (A) | Photopolymerizable | A1 | 36 | | 36 | 36 | | 36 | 36 | | 36 |
| | compound having | A2 | | 36 | | | 36 | | | 36 | |
| | ethylenically | | | | | | | | | | |
| | unsaturated | | | | | | | | | | |
| | group and | | | | | | | | | | |
| | acidic substituent | | | | | | | | | | |
| (B) | Thermosetting resin | B1: YX-4000 | 12 | 12 | 12 | 12 | 12 | 12 | 12 | 12 | 12 |
| (C) | Cross-linking agent | C1: DPHA | 7.4 | 7.4 | | 7.4 | 7.4 | | 7.4 | 7.4 | |
| | | C2: TMPTA | | | 7.4 | | | 7.4 | | | 7.4 |
| (D) | Elastomer | D1: Ricon131MA17 | 4 | 4 | 4 | 4 | 4 | 4 | 4 | 4 | 4 |
| (X) | Particles that dissolve | X1: Magnesium | | | | | | | | | |
| | 95% by mass or more | hydroxide 1 | | | | | | | | | |
| | in aqueous sulfuric | X2: Magnesium | | | | | | | | | |
| | acid solution having | carbonate | | | | | | | | | |
| | concentration of 5 to | X3: Zinc oxide | | | | | | | | | |
| | 100 ml/L under | | | | | | | | | | |
| | conditions of 70° C. | X4: Magnesium | 46 | 46 | 46 | | | | | | |
| | for 20 minutes | hydroxide 2 | (28) | (28) | (28) | | | | | | |
| (E) | Inorganic filler | E1: Silica | | | | | | | 40 | 40 | 40 |
| | | | | | | | | | (28) | (28) | (28) |
| (I) | Photo- | I1: Photopoly- | 0.25 | 0.25 | 0.25 | 0.25 | 0.25 | 0.25 | 0.25 | 0.25 | 0.25 |
| | polymerization | merization | | | | | | | | | |
| | initiator | initiator 1 | | | | | | | | | |
| | | I2: Photopoly- | 0.04 | 0.04 | 0.04 | 0.04 | 0.04 | 0.04 | 0.04 | 0.04 | 0.04 |
| | | merization | | | | | | | | | |
| | | initiator 2 | | | | | | | | | |

| | | | | | | | | | | |
|---|---|---|---|---|---|---|---|---|---|---|
| Conditions of | Treatment | 50 | 50 | 50 | 50 | 50 | 50 | 50 | 50 | 50 |
| particle (X) | temperature (° C.) | | | | | | | | | |
| dissolving step (3-2) | Treatment time (min) | 5 | 5 | 5 | 5 | 5 | 5 | 5 | 5 | 5 |

| | | | | | | | | | | |
|---|---|---|---|---|---|---|---|---|---|---|
| Evaluation | 1. Surface roughness [μm] | 0.13 | 0.11 | 0.14 | 0.04 | 0.03 | 0.03 | 0.06 | 0.07 | 0.06 |
| results | 2. Adhesive strength with | 0.52 | 0.54 | 0.55 | 0.01 | 0.01 | 0.01 | 0.23 | 0.21 | 0.2 |
| | plated copper [kN/m] | | | | | | | | | |

- The unit of content is parts by mass, and is solid content equivalent in the case of solution or dispersion.
Note
that numbers in parentheses indicate vol % relative to the solid content.

The components used in Table 1 are as follows.

### [Photopolymerizable Compound (A) Having Ethylenically Unsaturated Group and Acidic Substituent]

A1: Photopolymerizable compound (A1) having an ethylenically unsaturated group and an acidic substituent obtained in Synthesis Example 1, containing an alicyclic skeleton
A2: Photopolymerizable compound (A2) having an ethylenically unsaturated group and an acidic substituent obtained in Synthesis Example 2, not containing an alicyclic skeleton

### [Thermosetting Resin (B)]

B1: “YX-4000” (manufactured by Mitsubishi Chemical Corporation, biphenyl aralkyl type epoxy resin, epoxy equivalent: 180 to 192 g/eq)

### [Crosslinking Agent (C)]

C1: “DPHA” (dipentaerythritol hexaacrylate)
C2: “TMPTA” (trimethylolpropane triacrylate)

### [Elastomer (D)]

D1: “Ricon (registered trademark) 131MA17” (manufactured by Cray Valley, maleic acid modified polybutadiene, number average molecular weight 54,000 (catalog value))
   [Particles (X) (Particles that Dissolve 95% by Mass or More in an Aqueous Sulfuric Acid Solution Having a Concentration of 5 to 100 ml/L Under Conditions of 70° C. For 20 Minutes)]
X1: Magnesium hydroxide 1: “ECOMAG (registered trademark) Z-10” (magnesium hydroxide, volume average particle diameter 1.2 μm, manufactured by Tateho Chemical Industries Co., Ltd.)
X2: “Magthermo MS-S” (magnesium carbonate, volume average particle diameter 1.2 μm, manufactured by Konoshima Chemical Co., Ltd.)
X3: “LPZINC-KS-2” (zinc oxide, volume average particle diameter 2 μm, manufactured by SAKAI CHEMICAL INDUSTRY CO., LTD.)
X4: Magnesium hydroxide 2: “Magseeds (registered trademark) V-6F” (magnesium hydroxide, volume average particle diameter 0.9 μm, manufactured by Konoshima Chemical Co., Ltd.)

### [Inorganic Filler (E)]

E1: Spherical fused silica (volume average particle size 0.5 μm)

### [Photopolymerization Initiator (I)]

I1: Photopolymerization initiator 1: 2-methyl-1-[4-(methylthio)phenyl]-2-morpholinopropan-1-one, acetophenone-based compound
12: Photopolymerization initiator 2: 2,4-diethylthioxanthone, thioxanthone-based compound

From Table 1, it can be seen that in Examples 1 to 12, the adhesive strength with the plated copper was successfully increased while keeping the surface roughness of the interlayer insulating layer small. It is presumed that this is due to the particles (X) present on the surface of the interlayer insulating layer dissolving to form recesses, as shown in FIGS. 9 to 12.

On the other hand, in Comparative Examples 1 to 3, which used the particles (X), the surface roughness was small due to the absence of the particles, but in this case, the peel strength with the plated copper was extremely low. Further, in Comparative Examples 4 to 6, in which an inorganic filler other than the particles (X) was used instead of the particles (X), the peel strength with the plated copper was low when the surface roughness was small. It is presumed that this is due to the presence of the inorganic filler on the surface of the interlayer insulating layer, as shown in FIG. 13.

### Example 13 and Comparative Example 7

In the same manner as in Example 1 and Comparative Example 4, each photosensitive resin film was prepared, and an “evaluation laminate” having a cured product formed on the copper-clad laminate substrate was obtained through the lamination step (1). Then, the following operations were performed.

### (Roughening Treatment Step (3-1): Dry Etching)

The surface of the evaluation laminate obtained above was subjected to plasma treatment using oxygen plasma under conditions of output 300 W, temperature 25° C., and treatment time 5 minutes.

### (Particle (X) Dissolving Step (3-2) and Circuit Pattern Forming Step (4))

Subsequently, it was treated for 5 minutes with the alkaline cleaner “Cleaner Securiganth 902” (trade name, manufactured by Atotech Japan K.K.) at 60° C., followed by stored water washing at 25° C. for 1 minute and then running water washing at 25° C. for 3 minutes. Here, in Example 13, the surface of the obtained evaluation laminate was measured with the scanning electron microscope (SEM) (magnification: 10,000 times) and the surface image was taken. The results are shown in FIG. 14.

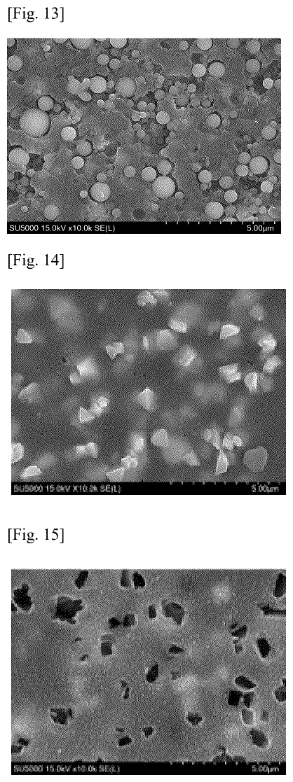

Subsequently, the surface of the evaluation laminate was treated with a mixed solution of sodium persulfate and an aqueous sulfuric acid solution (sulfuric acid concentration: 18.5 ml/L) at 27° C. for 30 seconds to perform soft etching and dissolve the particles (X). This treatment was performed not only in Example 13 but also in Comparative Example 7, which did not use the particles (X). Thereafter, it was washed in stored water at 25° C. for 1 minute, and then washed in running water at 25° C. for 3 minutes. Here, in Example 13, the surface of the obtained evaluation laminate was measured with the scanning electron microscope (SEM) (magnification: 10,000 times) and the surface image was taken. The results are shown in FIG. 15.

After the above treatment, the evaluation laminate was treated with the pre-dip liquid “Pre-dip Neoganth B” (trade name, manufactured by Atotech Japan K.K.) at 25° C. for 1 minute. Thereafter, the evaluation laminate was treated with the activator liquid “Activator Neoganth 834” (trade name, manufactured by Atotech Japan K.K.) at 40° C. for 5 minutes, followed by stored water washing at 25° C. for 1 minute and then running water washing at 25° C. for 3 minutes.

Subsequently, the evaluation laminate was treated with a reducing liquid “Reducer Neoganth WA” (trade name, manufactured by Atotech Japan K.K.) at 30° C. for 5 minutes, followed by stored water washing at 25° C. for 1 minute and then running water washing at 25° C. for 3 minutes.

The evaluation laminate thus obtained was placed in the chemical copper solution (“Basic Printganth MV-TP1”, “Copper Printganth MV-TP1”, “Moderator Printganth MV-TP1”, “Stabilizer Printganth MV-TP1”, “Reducer Cu” (all trade names, manufactured by Atotech Japan K.K.) and sodium hydroxide) and the electroless plating was performed until the plating thickness reached approximately 0.5 μm. After the electroless plating, the annealing treatment was performed for 30 minutes at a temperature of 120° C. to remove the remaining hydrogen gas. Thereafter, the copper sulfate electrolytic plating was performed, and the annealing treatment was performed at 180° C. for 60 minutes to form the conductor layer with a thickness of 25 μm. This evaluation laminate is referred to as evaluation laminate C.

Thereafter, the circuit pattern was formed on the evaluation laminate C by the semi-additive step. The measurement and evaluation results are shown in Table 2.

TABLE 2

| | | | | Comparative |
|---|---|---|---|---|
| | | | Example | Example |
| | | | 13 | 7 |
| (A) | Photopolymerizable compound | A1 | 36 | 36 |
| | having ethylenically unsaturated | A2 | | |
| | group and acidic substituent | | | |
| (B) | Thermosetting resin | B1: YX-4000 | 12 | 12 |
| (C) | Cross-linking agent | C1: DPHA | 7.4 | 7.4 |
| | | C2: TMPTA | | |
| (D) | Elastomer | D1: Ricon131MA17 | 4 | 4 |
| (X) | Particles that dissolve 95% by mass | X1: Magnesium hydroxide 1 | 46 (28) | |
| | or more in aqueous sulfuric acid | X2: Magnesium carbonate | | |
| | solution having concentration of | X3: Zinc oxide | | |
| | 5 to 100 ml/L under conditions of | X4: Magnesium hydroxide 2 | | |
| | 70° C. for 20 minutes | | | |
| (E) | Inorganic filler | E1: Silica | | 40 (28) |
| (I) | Photopolymerization initiator | I1: Photopolymerization | 0.25 | 0.25 |
| | | initiator 1 | | |
| | | I2: Photopolymerization | 0.04 | 0.04 |
| | | initiator 2 | | |

| | | | |
|---|---|---|---|
| Conditions of particle (X) | Treatment temperature (° C.) | 27 | 27 |
| dissolving step (3-2) | Treatment time (min) | 0.5 | 0.5 |

| | | | |
|---|---|---|---|
| Evaluation | 1. Surface roughness [μm] | 0.08 | 0.06 |
| results | 2. Adhesive strength with plated copper [kN/m] | 0.63 | 0.13 |

The unit of content is parts by mass, and is solid content equivalent in the case of solution or dispersion.
Note that numbers in parentheses indicate vol % relative to the solid content.

From Table 2, it can be seen that in Example 13, as can be seen from change in the surface of the interlayer insulating layer from FIG. 14 to FIG. 15, the particles (X) dissolved after the particle (X) dissolving step (3-2), and as a result, it was possible to successfully increase the adhesive strength with the plated copper while keeping the surface roughness of the interlayer insulating layer small.

On the other hand, in Comparative Example 7, in which the inorganic filler other than the particles (X) was used instead of the particles (X), the peel strength with the plated copper was low when the surface roughness was small.

### Example 14 and Comparative Example 8

In the same manner as in Example 2 and Comparative Example 5, each photosensitive resin film was prepared, and an “evaluation laminate” having a cured product formed on the copper-clad laminate substrate was obtained through the lamination step (1). Then, the following operations were performed.

### (Roughening Treatment Step (3-1); Dry Etching)

The surface of the evaluation laminate obtained above was subjected to plasma treatment using oxygen plasma under the conditions of output 300 W, temperature 25° C., and treatment time 5 minutes.

### (Particle (X) Dissolving Step (3-2))

The surface of the evaluation laminate that had been subjected to the plasma treatment was heated to a temperature shown in Table 3 in “Reduction Solution Securiganth MV” (trade name, manufactured by Atotech Japan K.K.) (total amount: 2,000 ml) to which the aqueous sulfuric acid solution was added so that the sulfuric acid concentration was 49 ml/L, and then the evaluation laminate was immersed for a time shown in Table 3. This treatment was performed not only in Example 14 but also in Comparative Example 8, which did not use the particles (X).

### (Circuit Pattern Forming Step (4))

Subsequently, the laminate was treated with the alkaline cleaner “Cleaner Securiganth 902” (trade name, manufactured by Atotech Japan K.K.) at 60° C. for 5 minutes, followed by stored water washing at 25° C. for 1 minute and then running water washing at 25° C. for 3 minutes.

Subsequently, the surface of the evaluation laminate was treated with the mixed solution of sodium persulfate and the aqueous sulfuric acid solution (sulfuric acid concentration: 18.5 ml/L) at 27° C. for 0.5 minutes to perform soft etching. Thereafter, the stored water washing at 25° C. for 1 minute was performed and then the running water washing at 25° C. for 3 minutes was performed.

After the above treatment, the evaluation laminate was treated with the pre-dip liquid “Pre-dip Neoganth B” (trade name, manufactured by Atotech Japan K.K.) at 25° C. for 1 minute. Thereafter, the evaluation laminate was treated with the activator liquid “Activator Neoganth 834” (trade name, manufactured by Atotech Japan K.K.) at 40° C. for 5 minutes, followed by stored water washing at 25° C. for 1 minute and then running water washing at 25° C. for 3 minutes.

Subsequently, the evaluation laminate was treated with the reducing liquid “Reducer Neoganth WA” (trade name, manufactured by Atotech Japan K.K.) at 30° C. for 5 minutes, followed by stored water washing at 25° C. for 1 minute and then running water washing at 25° C. for 3 minutes.

The evaluation laminate thus obtained was placed in the chemical copper solution (“Basic Printganth MV-TP1”, “Copper Printganth MV-TP1”, “Moderator Printganth MV-TP1”, “Stabilizer Printganth MV-TP1”, “Reducer Cu” (all trade names, manufactured by Atotech Japan K.K.) and sodium hydroxide) and the electroless plating was performed until the plating thickness reached approximately 0.5 μm. After the electroless plating, the annealing treatment was performed for 30 minutes at a temperature of 120° C. to remove the remaining hydrogen gas. Thereafter, the copper sulfate electrolytic plating was performed, and the annealing treatment was performed at 180° C. for 60 minutes to form the conductor layer with a thickness of 25 μm. This evaluation laminate is referred to as the evaluation laminate C.

Thereafter, the circuit pattern was formed on the evaluation laminate C by the semi-additive step. The measurement and evaluation results are shown in Table 3.

TABLE 3

| | | | | Comparative |
|---|---|---|---|---|
| | | | Example | Example |
| | | | 14 | 8 |
| (A) | Photopolymerizable compound having | A1 | | |
| | ethylenically unsaturated group | A2 | 36 | 36 |
| | and acidic substituent | | | |
| (B) | Thermosetting resin | B1: YX-4000 | 12 | 12 |
| (C) | Cross-linking agent | C1: DPHA | 7.4 | 7.4 |
| | | C2: TMPTA | | |
| (D) | Elastomer | D1: Ricon131MA17 | 4 | 4 |
| (X | Particles that dissolve 95% by mass | X1: Magnesium hydroxide 1 | | |
| | or more in aqueous sulfuric acid | X2: Magnesium carbonate | 58 (28) | |
| | solution having concentration of | X3: Zinc oxide | | |
| | 5 to 100 ml/L under conditions of | X4: Magnesium hydroxide 2 | | |
| | 70° C. for 20 minutes | | | |
| (E) | Inorganic filler | E1: Silica | | 40 (28) |
| (I) | Photopolymerization initiator | I1: Photopolymerization | 0.25 | 0.25 |
| | | initiator 1 | | |
| | | I2: Photopolymerization | 0.04 | 0.04 |
| | | initiator 2 | | |

| | | | |
|---|---|---|---|
| Conditions of particle (X) | Treatment temperature (° C.) | 70 | 70 |
| dissolving step (3-2) | Treatment time (min) | 20 | 20 |

| | | | |
|---|---|---|---|
| Evaluation | 1. Surface roughness [μm] | 0.11 | 0.06 |
| results | 2. Adhesive strength with plated copper [kN/m] | 0.64 | 0.13 |

The unit of content is parts by mass, and is solid content equivalent in the case of solution or dispersion.
Note that numbers in parentheses indicate vol % relative to the solid content.

From Table 3, in Example 14, the particles (X) dissolved after the particle (X) dissolving step (3-2), and as a result, it can be said that the adhesive strength with the plated copper was successfully increased while keeping the surface roughness of the interlayer insulating layer small.

On the other hand, in Comparative Example 8, in which the inorganic filler other than the particles (X) was used instead of the particles (X), the peel strength with the plated copper was low when the surface roughness was small.

### REFERENCE SIGNS LIST

100A: Printed wiring board
1: Particle (X)
2: Recess
101: Substrate
102: Circuit pattern
103: Interlayer insulating layer
104: Via (Via hole)
105: Seed layer
106: Resist pattern
107: Copper circuit layer
108: Solder resist layer

1. A method for producing a printed wiring board, the method comprising the following (1) to (4):
(1) laminating a photosensitive resin film containing particles (X) that dissolve 95% by mass or more in an aqueous sulfuric acid solution having a concentration of 5 to 100 ml/L under conditions of 70° C. for 20 minutes onto one or both sides of a circuit board;
(2) forming an interlayer insulating layer having a via by exposing and developing the photosensitive resin film laminated in the (1);
(3-1) performing roughening treatment on surfaces of the via and the interlayer insulating layer;
(3-2) dissolving the particles (X) present on the surface of the interlayer insulating layer by treating the interlayer insulating layer subjected to the roughening treatment with an acidic solution; and
(4) forming a circuit pattern on the interlayer insulating layer.

2. The method for producing the printed wiring board according to claim 1, wherein the roughening treatment in the (3-1) is performed using a roughening liquid.

3. The method for producing the printed wiring board according to claim 1, wherein the roughening treatment in the (3-1) is performed by dry etching.

4. The method for producing the printed wiring board according to claim 1, wherein surface roughness (Ra) of the interlayer insulating layer after the roughening treatment in the (3-1) is 0.30 μm or less.

5. The method for producing the printed wiring board according to claim 1, wherein the acidic solution used in the (3-2) comprises an aqueous sulfuric acid solution.

6. The method for producing the printed wiring board according to claim 1, wherein the particles (X) have a volume average particle diameter of 0.1 to 3 μm.

7. The method for producing the printed wiring board according to claim 1, wherein the photosensitive resin film contains 10 to 70 vol % of the particles (X).

8. A photosensitive resin composition comprising particles (X) that dissolve 95% by mass or more in an aqueous sulfuric acid solution having a concentration of 5 to 100 ml/L under conditions of 70° C. for 20 minutes.

9. The photosensitive resin composition according to claim 8, further comprising a component (A): a photopolymerizable compound having an ethylenically unsaturated group and an acidic substituent, and a component (B): a thermosetting resin.

10. The photosensitive resin composition according to claim 9, wherein the component (A) comprises an alicyclic skeleton represented by the following general formula (A-1) 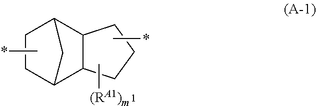
wherein, R^{A1} represents an alkyl group having 1 to 12 carbon atoms and may be substituted anywhere in the alicyclic skeleton, m¹ is an integer from 0 to 6, and * is a bonding site to another structure.

11. The photosensitive resin composition according to claim 8, wherein an average particle diameter of the particles (X) is 0.1 to 3 μm.

12. The photosensitive resin composition according to claim 8, wherein a content of the particles (X) is 10 to 70 vol % based on a total solid content.

13. A photosensitive resin composition for forming a photo via, comprising the photosensitive resin composition according to claim 8.

14. A photosensitive resin film comprising the photosensitive resin composition according to claim 8.

15. A printed wiring board comprising the photosensitive resin composition according to claim 8.

16. A semiconductor package comprising the printed wiring board according to claim 15 and a semiconductor element.
